(19) United States
(12) Patent Application Publication
(10) Pub. No.: US 2008/0106280 A1
(43) Pub. Date: May 8, 2008

(54) Vertical Microprobes for Contacting Electronic Components and Method for Making Such Probes

(75) Inventors: Richard T. Chen, Burbank, CA (US); Ezekiel J.J. Kruglick, San Diego, CA (US); Christopher A. Bang, San Diego, CA (US); Vacit Arat, La Canada Flintridge, CA (US); Adam L. Cohen, Van Nuys, CA (US); Kieun Kim, Pasadena, CA (US); Gang Zhang, Monterey Park, CA (US); Dennis R. Smalley, Newhall, CA (US)

Correspondence Address: MICROFABRICA INC.;ATT: DENNIS R. SMALLEY, 7911 HASKELL AVENUE, VAN NUYS, CA, 91406, US

(73) Assignee: Microfabrica Inc.

(21) Appl. No.: 11/928,707

(22) Filed: Oct. 30, 2007

Related U.S. Application Data
(63) Continuation of application No. 11/325,404, filed on Jan. 3, 2006.
(63) Continuation-in-part of application No. 10/949,738, filed on Sep. 24, 2004, now abandoned.
(63) Continuation-in-part of application No. 11/029,180, filed on Jan. 3, 2005, now abandoned.
Application No. 10/949,738 is a continuation-in-part of application No. 10/772,943, filed on Feb. 4, 2004, now abandoned.
Application No. 10/949,738 is a continuation-in-part of application No. 10/949,738, filed on Sep. 24, 2004, now abandoned.
(60) Provisional application No. 60/641,341, filed on Jan. 3, 2005.
(60) Provisional application No. 60/445,186, filed on Feb. 4, 2003.
(60) Provisional application No. 60/506,015, filed on Sep. 24, 2003.
(60) Provisional application No. 60/533,933, filed on Dec. 31, 2003.
(60) Provisional application No. 60/536,865, filed on Jan. 15, 2004.
(60) Provisional application No. 60/506,015, filed on Sep. 24, 2003.
(60) Provisional application No. 60/533,933, filed on Dec. 31, 2003.
(60) Provisional application No. 60/536,865, filed on Jan. 15, 2004.
(60) Provisional application No. 60/533,933, filed on Dec. 31, 2003.
(60) Provisional application No. 60/536,865, filed on Jan. 15, 2004.
(60) Provisional application No. 60/540,511, filed on Jan. 29, 2004.
(60) Provisional application No. 60/582,726, filed on Jun. 23, 2004.
(60) Provisional application No. 60/540,510, filed on Jan. 29, 2004.
(60) Provisional application No. 60/533,897, filed on Dec. 31, 2003.

(51) Int. Cl. G01R 1/067

(52) U.S. Cl. 324/754

(57) ABSTRACT

Multilayer probe structures for testing or otherwise making electrical contact with semiconductor die or other electronic components are electrochemically fabricated via depositions of one or more materials in a plurality of overlaying and adhered layers. In some embodiments the structures may include configurations intended to enhance functionality, buildability, or both.

### RELATED APPLICATIONS

This application is a continuation of U.S. patent application Ser. No. 11/325,404 which claims benefit of U.S. App. Nos. 60/641,341, filed Jan. 3, 2005; the '404 application is also is a continuation-in-part of U.S. application Ser. Nos. 10/949,738, filed Sep. 24, 2004, and 11/029,180, filed Jan. 3, 2005. The '738 application is a continuation-in-part of U.S. Non-Provisional patent application Ser. No. 10/772,943 filed on Feb. 4, 2004, which in turn claims benefit of U.S. Provisional Patent Application Nos. 60/445,186; 60/506,015; 60/533,933, and 60/536,865 filed on Feb. 4, 2003; Sep. 24, 2003; Dec. 31, 2003; and Jan. 15, 2004 respectively; furthermore the '738 application claims benefit of U.S. Provisional Patent Application Nos. 60/506,015; 60/533,933; and 60/536,865 filed on Sep. 24, 2003; Dec. 31, 2003; and Jan. 15, 2004, respectively. The '180 application claims benefit of U.S. App. Nos. 60/533,933, 60/536,865, 60/540,511, 60/582,726, 60/540,510, and 60/533,897 and is a continuation-in-part of U.S. application Ser. No. 10/949,738. Each of these applications, including any appendices attached thereto, is incorporated herein by reference as if set forth in full herein.

### FIELD OF THE INVENTION

Embodiments of the present invention relate to microprobes (e.g. for use in the wafer level testing of integrated circuits) and more particularly to microprobes that have a base end and a contact tip end which makes contact with an electronic component has it is compressed toward the base end. Other embodiments pertain to fabrication of such probes using electrochemical fabrication methods.

### BACKGROUND OF THE INVENTION

Electrochemical Fabrication:

A technique for forming three-dimensional structures (e.g. parts, components, devices, and the like) from a plurality of adhered layers was invented by Adam L. Cohen and is known as Electrochemical Fabrication. It is being commercially pursued by Microfabrica Inc. (formerly MEMGen® Corporation) of Burbank, Calif. under the name EFAB™. This technique was described in U.S. Pat. No. 6,027,630, issued on Feb. 22, 2000. This electrochemical deposition technique allows the selective deposition of a material using a unique masking technique that involves the use of a mask that includes patterned conformable material on a support structure that is independent of the substrate onto which plating will occur. When desiring to perform an electrodeposition using the mask, the conformable portion of the mask is brought into contact with a substrate while in the presence of a plating solution such that the contact of the conformable portion of the mask to the substrate inhibits deposition at selected locations. For convenience, these masks might be generically called conformable contact masks; the masking technique may be generically called a conformable contact mask plating process. More specifically, in the terminology of Microfabrica Inc. (formerly MEMGen® Corporation) of Burbank, Calif. such masks have come to be known as INSTANT MASKS™ and the process known as INSTANT MASKING™ or INSTANT MASK™ plating. Selective depositions using conformable contact mask plating may be used to form single layers of material or may be used to form multi-layer structures. The teachings of the '630 patent are hereby incorporated herein by reference as if set forth in full herein. Since the filing of the patent application that led to the above noted patent, various papers about conformable contact mask plating (i.e. INSTANT MASKING) and electrochemical fabrication have been published:
1. A. Cohen, G. Zhang, F. Tseng, F. Mansfeld, U. Frodis and P. Will, “EFAB: Batch production of functional, fully-dense metal parts with micro-scale features”, Proc. 9th Solid Freeform Fabrication, The University of Texas at Austin, p 161, Aug. 1998.
2. A. Cohen, G. Zhang, F. Tseng, F. Mansfeld, U. Frodis and P. Will, “EFAB: Rapid, Low-Cost Desktop Micromachining of High Aspect Ratio True 3-D MEMS”, Proc. 12th IEEE Micro Electro Mechanical Systems Workshop, IEEE, p 244, January 1999.
3. A. Cohen, “3-D Micromachining by Electrochemical Fabrication”, Micromachine Devices, March 1999.
4. G. Zhang, A. Cohen, U. Frodis, F. Tseng, F. Mansfeld, and P. Will, “EFAB: Rapid Desktop Manufacturing of True 3-D Microstructures”, Proc. 2nd International Conference on Integrated MicroNanotechnology for Space Applications, The Aerospace Co., Apr. 1999.
5. F. Tseng, U. Frodis, G. Zhang, A. Cohen, F. Mansfeld, and P. Will, “EFAB: High Aspect Ratio, Arbitrary 3-D Metal Microstructures using a Low-Cost Automated Batch Process”, 3rd International Workshop on High Aspect Ratio MicroStructure Technology (HARMST'99), June 1999.
6. A. Cohen, U. Frodis, F. Tseng, G. Zhang, F. Mansfeld, and P. Will, “EFAB: Low-Cost, Automated Electrochemical Batch Fabrication of Arbitrary 3-D Microstructures”, Micromachining and Microfabrication Process Technology, SPIE 1999 Symposium on Micromachining and Microfabrication, September 1999.
7. F. Tseng, G. Zhang, U. Frodis, A. Cohen, F. Mansfeld, and P. Will, “EFAB: High Aspect Ratio, Arbitrary 3-D Metal Microstructures using a Low-Cost Automated Batch Process”, MEMS Symposium, ASME 1999 International Mechanical Engineering Congress and Exposition, November, 1999.
8. A. Cohen, “Electrochemical Fabrication (EFAB™)”, Chapter 19 of The MEMS Handbook, edited by Mohamed Gad-El-Hak, CRC Press, 2002.
9. Microfabrication—Rapid Prototyping's Killer Application”, pages 1-5 of the Rapid Prototyping Report, CAD/CAM Publishing, Inc., June 1999.

The disclosures of these nine publications are hereby incorporated herein by reference as if set forth in full herein.

The electrochemical deposition process may be carried out in a number of different ways as set forth in the above patent and publications. In one form, this process involves the execution of three separate operations during the formation of each layer of the structure that is to be formed:
1. Selectively depositing at least one material by electrodeposition upon one or more desired regions of a substrate.
2. Then, blanket depositing at least one additional material by electrodeposition so that the additional deposit covers both the regions that were previously selectively deposited onto, and the regions of the substrate that did not receive any previously applied selective depositions.
3. Finally, planarizing the materials deposited during the first and second operations to produce a smoothed surface of a first layer of desired thickness having at least one region containing the at least one material and at least one region containing at least the one additional material.

After formation of the first layer, one or more additional layers may be formed adjacent to the immediately preceding layer and adhered to the smoothed surface of that preceding layer. These additional layers are formed by repeating the first through third operations one or more times wherein the formation of each subsequent layer treats the previously formed layers and the initial substrate as a new and thickening substrate.

Once the formation of all layers has been completed, at least a portion of at least one of the materials deposited is generally removed by an etching process to expose or release the three-dimensional structure that was intended to be formed.

The preferred method of performing the selective electrodeposition involved in the first operation is by conformable contact mask plating. In this type of plating, one or more conformable contact (CC) masks are first formed. The CC masks include a support structure onto which a patterned conformable dielectric material is adhered or formed. The conformable material for each mask is shaped in accordance with a particular cross-section of material to be plated. At least one CC mask is needed for each unique cross-sectional pattern that is to be plated.

The support for a CC mask is typically a plate-like structure formed of a metal that is to be selectively electroplated and from which material to be plated will be dissolved. In this typical approach, the support will act as an anode in an electroplating process. In an alternative approach, the support may instead be a porous or otherwise perforated material through which deposition material will pass during an electroplating operation on its way from a distal anode to a deposition surface. In either approach, it is possible for CC masks to share a common support, i.e. the patterns of conformable dielectric material for plating multiple layers of material may be located in different areas of a single support structure. When a single support structure contains multiple plating patterns, the entire structure is referred to as the CC mask while the individual plating masks may be referred to as “submasks”. In the present application such a distinction will be made only when relevant to a specific point being made.

In preparation for performing the selective deposition of the first operation, the conformable portion of the CC mask is placed in registration with and pressed against a selected portion of the substrate (or onto a previously formed layer or onto a previously deposited portion of a layer) on which deposition is to occur. The pressing together of the CC mask and substrate occur in such a way that all openings, in the conformable portions of the CC mask contain plating solution. The conformable material of the CC mask that contacts the substrate acts as a barrier to electrodeposition while the openings in the CC mask that are filled with electroplating solution act as pathways for transferring material from an anode (e.g. the CC mask support) to the non-contacted portions of the substrate (which act as a cathode during the plating operation) when an appropriate potential and/or current are supplied.

An example of a CC mask and CC mask plating are shown in FIGS. 1A-1C. FIG. 1A shows a side view of a CC mask 8 consisting of a conformable or deformable (e.g. elastomeric) insulator 10 patterned on an anode 12. The anode has two functions. One is as a supporting material for the patterned insulator 10 to maintain its integrity and alignment since the pattern may be topologically complex (e.g., involving isolated “islands” of insulator material). The other function is as an anode for the electroplating operation. FIG. 1A also depicts a substrate 6 separated from mask 8. CC mask plating selectively deposits material 22 onto a substrate 6 by simply pressing the insulator against the substrate then electrodepositing material through apertures 26a and 26b in the insulator as shown in FIG. 1B. After deposition, the CC mask is separated, preferably non-destructively, from the substrate 6 as shown in FIG. 1C. The CC mask plating process is distinct from a “through-mask” plating process in that in a through-mask plating process the separation of the masking material from the substrate would occur destructively. As with through-mask plating, CC mask plating deposits material selectively and simultaneously over the entire layer. The plated region may consist of one or more isolated plating regions where these isolated plating regions may belong to a single structure that is being formed or may belong to multiple structures that are being formed simultaneously. In CC mask plating, as individual masks are not intentionally destroyed in the removal process, they may be usable in multiple plating operations.

Another example of a CC mask and CC mask plating is shown in FIGS. 1D-1G. FIG. 1D shows an anode 12′ separated from a mask 8′ that includes a patterned conformable material 10′ and a support structure 20. FIG. 1D also depicts substrate 6 separated from the mask 8′. FIG. 1E illustrates the mask 8′ being brought into contact with the substrate 6. FIG. 1F illustrates the deposit 22′ that results from conducting a current from the anode 12′ to the substrate 6. FIG. 1G illustrates the deposit 22′ on substrate 6 after separation from mask 8′. In this example, an appropriate electrolyte is located between the substrate 6 and the anode 12′ and a current of ions coming from one or both of the solution and the anode are conducted through the opening in the mask to the substrate where material is deposited. This type of mask may be referred to as an anodeless INSTANT MASK™ (AIM) or as an anodeless conformable contact (ACC) mask.

Unlike through-mask plating, CC mask plating allows CC masks to be formed completely separate from the fabrication of the substrate on which plating is to occur (e.g. separate from a three-dimensional (3D) structure that is being formed). CC masks may be formed in a variety of ways, for example, a photolithographic process may be used. All masks can be generated simultaneously prior to structure fabrication rather than during it. This separation makes possible a simple, low-cost, automated, self-contained, and internally-clean “desktop factory” that can be installed almost anywhere to fabricate 3D structures, leaving any required clean room processes, such as photolithography to be performed by service bureaus or the like.

An example of the electrochemical fabrication process discussed above is illustrated in FIGS. 2A-2F. These figures show that the process involves deposition of a first material 2 which is a sacrificial material and a second material 4 which is a structural material. The CC mask 8, in this example, includes a patterned conformable material (e.g. an elastomeric dielectric material) 10 and a support 12 which is made from deposition material 2. The conformal portion of the CC mask is pressed against substrate 6 with a plating solution 14 located within the openings 16 in the conformable material 10. An electric current, from power supply 18, is then passed through the plating solution 14 via (a) support 12 which doubles as an anode and (b) substrate 6 which doubles as a cathode. FIG. 2A, illustrates that the passing of current causes material 2 within the plating solution and material 2 from the anode 12 to be selectively transferred to and plated on the substrate 6. After electroplating the first deposition material 2 onto the substrate 6 using CC mask 8, the CC mask 8 is removed as shown in FIG. 2B. FIG. 2C depicts the second deposition material 4 as having been blanket-deposited (i.e. non-selectively deposited) over the previously deposited first deposition material 2 as well as over the other portions of the substrate 6. The blanket deposition occurs by electroplating from an anode (not shown), composed of the second material, through an appropriate plating solution (not shown), and to the cathode/substrate 6. The entire two-material layer is then planarized to achieve precise thickness and flatness as shown in FIG. 2D. After repetition of this process for all layers, the multi-layer structure 20 formed of the second material 4 (i.e. structural material) is embedded in first material 2 (i.e. sacrificial material) as shown in FIG. 2E. The embedded structure is etched to yield the desired device, i.e. structure 20, as shown in FIG. 2F.

Various components of an exemplary manual electrochemical fabrication system 32 are shown in FIGS. 3A-3C. The system 32 consists of several subsystems 34, 36, 38, and 40. The substrate holding subsystem 34 is depicted in the upper portions of each of FIGS. 3A-3C and includes several components: (1) a carrier 48, (2) a metal substrate 6 onto which the layers are deposited, and (3) a linear slide 42 capable of moving the substrate 6 up and down relative to the carrier 48 in response to drive force from actuator 44. Subsystem 34 also includes an indicator 46 for measuring differences in vertical position of the substrate which may be used in setting or determining layer thicknesses and/or deposition thicknesses. The subsystem 34 further includes feet 68 for carrier 48 which can be precisely mounted on subsystem 36.

The CC mask subsystem 36 shown in the lower portion of FIG. 3A includes several components: (1) a CC mask 8 that is actually made up of a number of CC masks (i.e. submasks) that share a common support/anode 12, (2) precision X-stage 54, (3) precision Y-stage 56, (4) frame 72 on which the feet 68 of subsystem 34 can mount, and (5) a tank 58 for containing the electrolyte 16. Subsystems 34 and 36 also include appropriate electrical connections (not shown) for connecting to an appropriate power source (not shown) for driving the CC masking process.

The blanket deposition subsystem 38 is shown in the lower portion of FIG. 3B and includes several components: (1) an anode 62, (2) an electrolyte tank 64 for holding plating solution 66, and (3) frame 74 on which feet 68 of subsystem 34 may sit. Subsystem 38 also includes appropriate electrical connections (not shown) for connecting the anode to an appropriate power supply (not shown) for driving the blanket deposition process.

The planarization subsystem 40 is shown in the lower portion of FIG. 3C and includes a lapping plate 52 and associated motion and control systems (not shown) for planarizing the depositions.

In addition to teaching the use of CC masks for electrodeposition purposes, the '630 patent also teaches that the CC masks may be placed against a substrate with the polarity of the voltage reversed and material may thereby be selectively removed from the substrate. It indicates that such removal processes can be used to selectively etch, engrave, and polish a substrate, e.g., a plaque.

Another method for forming microstructures from electroplated metals (i.e. using electrochemical fabrication techniques) is taught in U.S. Pat. No. 5,190,637 to Henry Guckel, entitled “Formation of Microstructures by Multiple Level Deep X-ray Lithography with Sacrificial Metal layers”. This patent teaches the formation of metal structure utilizing mask exposures. A first layer of a primary metal is electroplated onto an exposed plating base to fill a void in a photoresist, the photoresist is then removed and a secondary metal is electroplated over the first layer and over the plating base. The exposed surface of the secondary metal is then machined down to a height which exposes the first metal to produce a flat uniform surface extending across the both the primary and secondary metals. Formation of a second layer may then begin by applying a photoresist layer over the first layer and then repeating the process used to produce the first layer. The process is then repeated until the entire structure is formed and the secondary metal is removed by etching. The photoresist is formed over the plating base or previous layer by casting and the voids in the photoresist are formed by exposure of the photoresist through a patterned mask via X-rays or UV radiation.

Electrochemical fabrication provides the ability to form prototypes and commercial quantities of miniature objects, parts, structures, devices, and the like at reasonable costs and in reasonable times. In fact, electrochemical fabrication is an enabler for the formation of many structures that were hitherto impossible to produce. Electrochemical fabrication opens the spectrum for new designs and products in many industrial fields. Even though electrochemical fabrication offers this new capability and it is understood that electrochemical fabrication techniques can be combined with designs and structures known within various fields to produce new structures, certain uses for electrochemical fabrication provide designs, structures, capabilities and/or features not known or obvious in view of the state of the art.

Electrical Contact Element Designs, Assembly, and Fabrication:

Compliant electrical contact elements (e.g. probes) can be used to make permanent or temporary electrical contact between electronic components. For example such contacts may be used to convey electrical signals between printed circuit boards, between space transformers and semiconductor devices under test, from probe cards to space transformers via an interposer, between sockets and semiconductors or other electrical/electronic components mounted thereto, and the like.

Various techniques for forming electrical contact elements, various designs for such contact elements, and various assemblies using such elements have been taught previously. Examples of such teachings may be found in U.S. Pat. Nos. 5,476,211; 5,917,707; 6,336,269; 5,772,451; 5,974,662; 5,829,128; 5,820,014; 6,023,103; 6,064,213; 5,994,152; 5,806,181; 6,482,013; 6,184,053; 6,043,563; 6,520,778; 6,838,893; 6,705,876; 6,441,315; 6,690,185; 6,483,328; 6,268,015; 6,456,099; 6,208,225; 6,218,910; 6,627,483; 6,640,415; 6,713,374; 6,672,875; 6,509,751; 6,539,531; 6,729,019; and 6,817,052. Each of these patents is incorporated herein by reference as if set forth in full. Various teachings set forth explicitly in this application may be supplemented by teachings set forth in these incorporated patents to define enhanced embodiments and aspects of the invention.

A need exists in various fields for miniature devices having improved characteristics, reduced fabrication times, reduced fabrication costs, simplified fabrication processes, and/or more independence between geometric configuration and the selected fabrication process. A need also exists in the field of miniature device fabrication for improved fabrication methods and apparatus.

### SUMMARY OF THE INVENTION

It is an object of some embodiments of the invention to provide compliant contact elements (e.g. microprobes) with improved over-travel capability.

It is an object of some embodiments of the invention to provide compliant contact elements with improved compliance.

It is an object of some embodiments of the invention to provide compliant contact elements with improved packing capability.

It is an object of some embodiments of the invention to provide compliant contact elements with improved scrubbing capability.

It is an object of some embodiments of the invention to provide compliant contact elements with improved current carrying ability.

It is an object of some embodiments of the invention to provide compliant contact elements with enhanced longevity.

It is an object of some embodiments of the invention to provide a fabrication process capable of reliability forming compliant contact elements and contact element arrays having desired attributes.

It is an object of some embodiments of the invention to provide a fabrication process capable of cost effectively and rapidly producing high quality compliant contact elements and element arrays.

It is an object of some embodiments of the invention to provide a fabrication process capable of reducing assembly time, cost, and manpower associated with forming arrays of compliant contact elements.

Other objects and advantages of various embodiments of the invention will be apparent to those of skill in the art upon review of the teachings herein. The various embodiments of the invention, set forth explicitly herein or otherwise ascertained from the teachings herein, may address one or more of the above objects alone or in combination, or alternatively may address some other object of the invention ascertained from the teachings herein. It is not necessarily intended that all objects be addressed by any single aspect of the invention even though that may be the case with regard to some aspects.

In a first aspect of the invention, a compliant probe device for making electric contact with an electronic component, includes: (A) a tip element; (B) an elongated compliant element formed from a plurality of adhered layers of a deposited material adhered to the tip element, wherein at least one of the following criteria is met: (1) the elongate compliant element comprises a plurality of steps with a number of the steps separated from adjacent steps by a bridge of material that is common to a lower adjacent step and a higher adjacent step; (2) the elongate compliant element comprises at least two compliant springs that are oriented so as to provide balanced compliance under compressive force; (3) the compliant element comprises a plurality of compliant spring elements located in parallel; (4) the compliant element comprises a plurality of compliant elements a portion of which are in parallel to each other and a portion which are in series with each other; (5) the compliant element is located in proximity to a stiffening element such that lateral displacement of the compliant element is hindered upon contact with the stiffening element; (6) the compliant element comprises a first spring element in series with a second spring element wherein during compression the first spring element is placed in a net compressive state while the second spring element is placed in a net tensional state; or (7) the compliant element comprises a first spring element in series with a second spring element, where the first spring element has a first compliance and the second spring element has a second compliance and where the first and second compliance are different.

In a second aspect of the invention, a compliant probe array for making electric contact with an electronic component, includes: (A) a plurality of tip elements; (B) a plurality of elongated compliant elements formed from a plurality of adhered layers of a deposited material with each elongate compliant element adhered to a respect tip element, wherein at least one of the following criteria is met: (1) the array is formed of elongate compliant elements with each comprising a plurality of steps with a number of the steps separated from adjacent steps by a bridge of material that is common to a lower adjacent step and a higher adjacent step wherein the bridging elements provide a spacing necessary to position adjacent probe elements apart from one another by a distance which is less than a cross-sectional width of the elongate elements; or (2) the array is formed of elongate compliant extension elements that may move independently of other elongate compliant extension elements which are position is series with a plurality of elongate compliant base elements whose movement is coupled to other compliant base elements but a bridging element that is located between the elongate compliant extension elements and the elongate compliant base elements.

Further aspects of the invention will be understood by those of skill in the art upon reviewing the teachings herein. Other aspects of the invention may involve apparatus and methods used in implementing the above noted aspect of the invention. These other aspects of the invention may provide various combinations of the aspects, embodiments, and associated alternatives explicitly set forth herein as well as provide other configurations, structures, functional relationships, and processes that have not been specifically set forth above.

### BRIEF DESCRIPTION OF THE DRAWINGS

FIGS. 1A-1C schematically depict side views of various stages of a CC mask plating process, while FIGS. 1D-1G schematically depict a side views of various stages of a CC mask plating process using a different type of CC mask.

FIGS. 2A-2F schematically depict side views of various stages of an electrochemical fabrication process as applied to the formation of a particular structure where a sacrificial material is selectively deposited while a structural material is blanket deposited.

FIGS. 3A-3C schematically depict side views of various example apparatus subassemblies that may be used in manually implementing the electrochemical fabrication method depicted in FIGS. 2A-2F.

FIGS. 4A-4F schematically depict the formation of a first layer of a structure using adhered mask plating where the blanket deposition of a second material overlays both the openings between deposition locations of a first material and the first material itself

FIG. 4G depicts the completion of formation of the first layer resulting from planarizing the deposited materials to a desired level.

FIGS. 4H and 4I respectively depict the state of the process after formation of the multiple layers of the structure and after release of the structure from the sacrificial material.

FIGS. 5A-5B provide perspective views of the bodies of two simple “staircase” probes.

FIGS. 5C-5E provide perspective views of somewhat more complex stair case probes.

FIGS. 6A and 6B provide perspective views of a linear array and a two-dimensional array, respectively, of staircase probes.

FIGS. 7A-7B provide a view of a jack probe and an array of jack probes, respectively, according to a second group of embodiments of the invention.

FIGS. 8-10 provide examples of a third group of embodiments of the present invention where perspective views of balanced probes are provided (FIGS. 8 and 9) and where an array of such probes is provided (FIG. 10).

FIGS. 11-15B depict examples of parallel spring structures whose stiffness increases with the addition of each spring element.

FIGS. 16A-18B depict examples of combination spring structures that have both repetitive parallel and series components.

FIGS. 19A-19B depict a perspective view and a schematic view from the top, respectively of an example of a fifth group of embodiments where lateral stiffness of vertical probes is increase by the presence of a stiffening element.

FIGS. 20A-20G provide additional schematic views of alternative probe and stiffening element configurations according to the fifth group of embodiments.

FIGS. 21-27 provide examples of probe structures according to a sixth group of embodiments of the invention where one elongated compliant element of the probe is placed in compression during contact while another elongated compliant element of the probe is placed in tension.

FIGS. 28A-28B. illustrate a side view of a probe structure having a stiffer element and a more compliant element (FIG. 28A) and a comparison graph of force versus deflection for a single probe structure C and a dual element probe structure A and B (FIG. 28B).

FIG. 29 provides a schematic illustration of a side view of an eight group of embodiments of the invention where enhanced compliance is provided.

FIG. 30 provides a side view of an alternative accordion-like probe that may be designed to provide a desired compliance and deflection according to a nineth group of embodiments of the invention.

FIG. 31 provides a side view of a three probe element array according to a tenth group of embodiments of the invention where vertical motion of the probe tips couples a horizontal motion that may result in enhanced scrubbing of probe tips against contact pads.

FIGS. 32A-32B provide schematic side views of two example probes according to an eleventh group of embodiments of the invention.

FIG. 33 provides a schematic side view of an example probe according to a twelfth group of embodiments where the probe has a cantilever arm which is supported by two legs one which extends to the rear of the cantilever and one which extends to and beyond the tip of the cantilever.

FIGS. 34A-34B provide schematic side views while FIGS. 35A-35B provide perspective view of various examples of self scrubbing probe tip designs according to a thirteenth group of embodiments of the invention.

FIG. 36A-36B provide perspective views of additional self scrubbing probe tip designs according to the thirteenth embodiment of the invention wherein the probe tips also provide a self cleaning configuration.

FIG. 37. provides a top schematic view of a probe head or tip configuration according to another embodiment of the thirteenth group of embodiments where the probe tips are elongated and where there configuration is effective in changing the effective compliance of the probe after contact is made with a pad.

FIG. 38. provides a perspective view of another example probe tip according to a fourteenth group of embodiments where the tip takes on a hollow cylindrical configuration that may function having split segments of the cylinder that extend below its ring like base element.

FIGS. 39A-39O provide SEM images of various alternative probe tip configurations that may be used in conjunction with the various embodiments set forth herein.

FIGS. 40A-42 provide side views of probe arrays and shielding structures according to a fifteenth group of embodiments of the invention.

### DETAILED DESCRIPTION OF PREFERRED EMBODIMENTS OF THE INVENTION

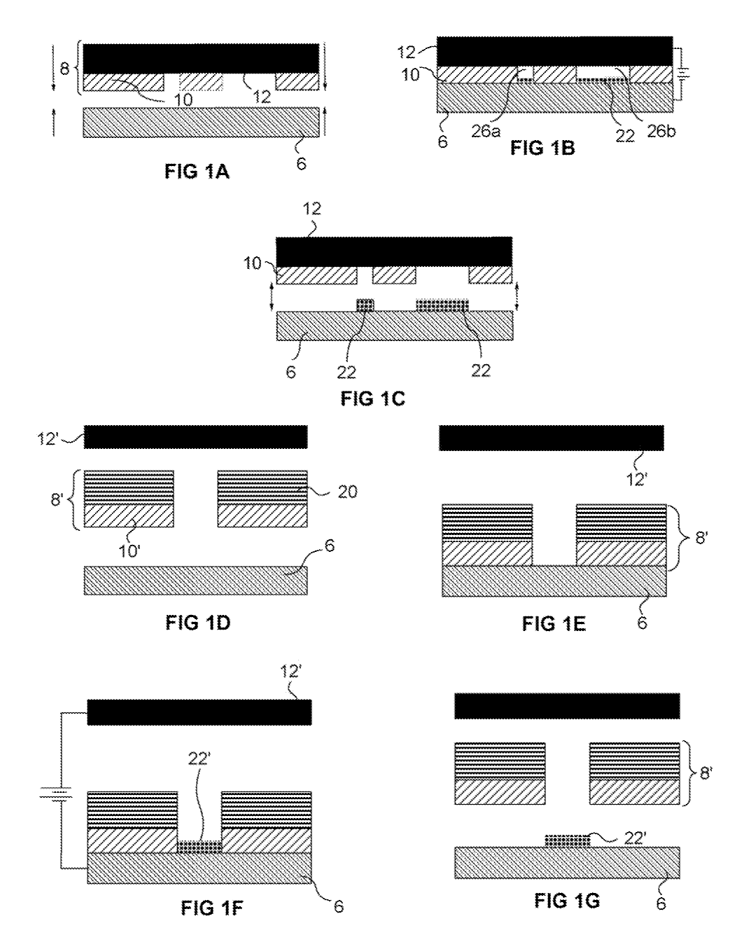

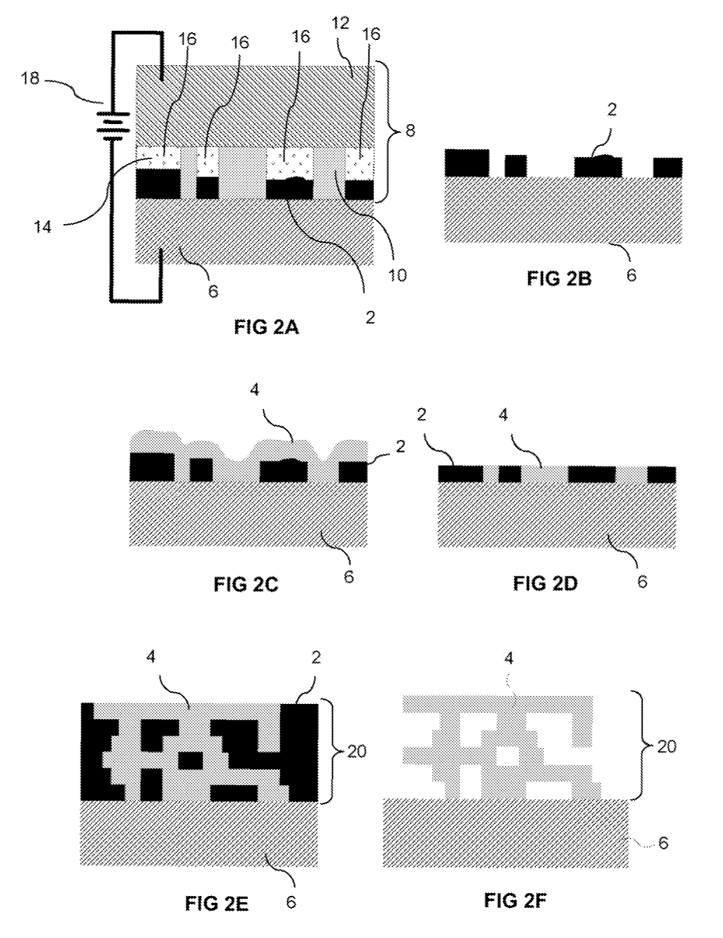

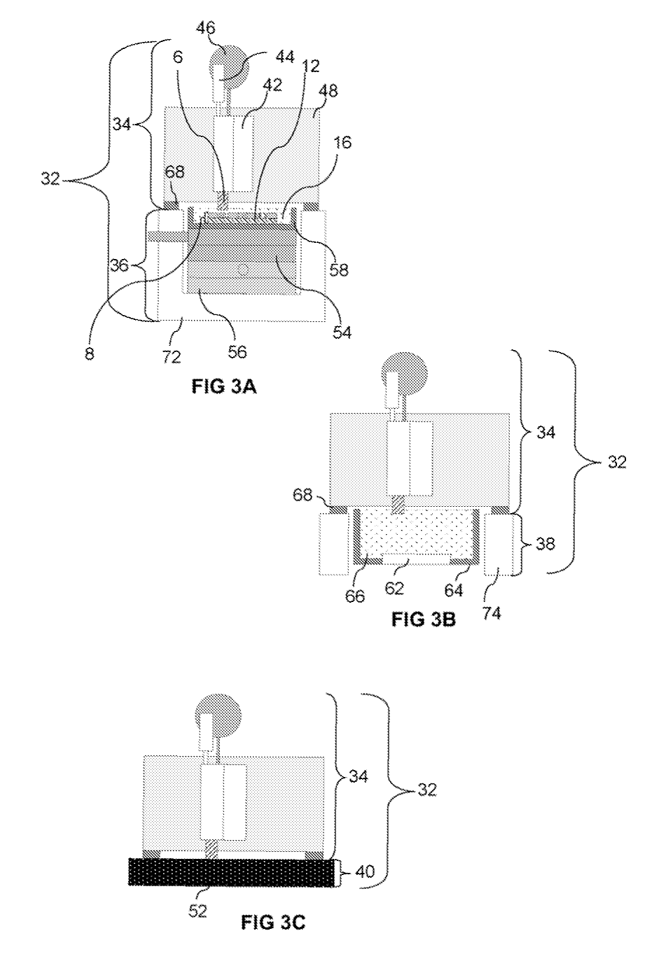

FIGS. 1A-1G, 2A-2F, and 3A-3C illustrate various features of one form of electrochemical fabrication. Other electrochemical fabrication techniques are set forth in the '630 patent referenced above, in the various previously incorporated publications, in various other patents and patent applications incorporated herein by reference. Still others may be derived from combinations of various approaches described in these publications, patents, and applications, or are otherwise known or ascertainable by those of skill in the art from the teachings set forth herein. All of these techniques may be combined with those of the various embodiments of various aspects of the invention to yield enhanced embodiments. Still other embodiments may be derived from combinations of the various embodiments explicitly set forth herein.

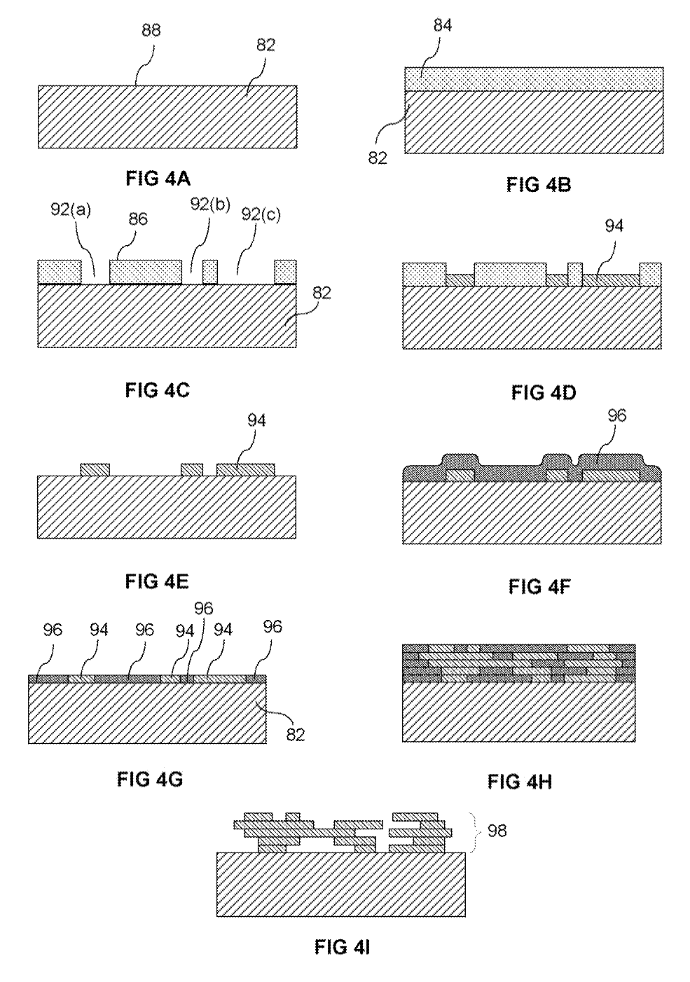

FIGS. 4A-4I illustrate various stages in the formation of a single layer of a multi-layer fabrication process where a second metal is deposited on a first metal as well as in openings in the first metal so that the first and second metal form part of the layer. In FIG. 4A a side view of a substrate 82 is shown, onto which patternable photoresist 84 is cast as shown in FIG. 4B. In FIG. 4C a pattern of resist is shown that results from the curing, exposing, and developing of the resist. The patterning of the photoresist 84 results in openings or apertures 92(a)-92(c) extending from a surface 86 of the photoresist through the thickness of the photoresist to surface 88 of the substrate 82. In FIG. 4D a metal 94 (e.g. nickel) is shown as having been electroplated into the openings 92(a)-92(c). In FIG. 4E the photoresist has been removed (i.e. chemically stripped) from the substrate to expose regions of the substrate 82 which are not covered with the first metal 94. In FIG. 4F a second metal 96 (e.g., silver) is shown as having been blanket electroplated over the entire exposed portions of the substrate 82 (which is conductive) and over the first metal 94 (which is also conductive). FIG. 4G depicts the completed first layer of the structure which has resulted from the planarization of the first and second metals down to a height that exposes the first metal and sets a thickness for the first layer. In FIG. 4H the result of repeating the process steps shown in FIGS. 4B-4G several times to form a multi-layer structure are shown where each layer consists of two materials. For most applications, one of these materials is removed as shown in FIG. 4I to yield a desired 3-D structure 98 (e.g. component or device).

Various embodiments of various aspects of the invention are directed to formation of three-dimensional structures from materials some of which may be electrodeposited or electroless deposited. Some of these structures may be formed form a single layer of one or more deposited materials while others are formed from a plurality of layers of deposited materials (e.g. 2 or more layers, more preferably five or more layers, and most preferably ten or more layers). In some embodiments structures having features positioned with micron level precision and minimum features size on the order of tens of microns are to be formed. In other embodiments structures with less precise feature placement and/or larger minimum features may be formed. In still other embodiments, higher precision and smaller minimum feature sizes may be desirable.

The various embodiments, alternatives, and techniques disclosed herein may be combined with or be implemented via electrochemical fabrication techniques. Such combinations or implementations may be used to form multi-layer structures using a single patterning technique on all layers or using different patterning techniques on different layers. For example, different types of patterning masks and masking techniques may be used or even techniques that perform direct selective depositions without the need for masking. For example, conformable contact masks may be used during the formation of some layers while non-conformable contact masks may be used in association with the formation of other layers. Proximity masks and masking operations (i.e. operations that use masks that at least partially selectively shield a substrate by their proximity to the substrate even if contact is not made) may be used, and adhered masks and masking operations (masks and operations that use masks that are adhered to a substrate onto which selective deposition or etching is to occur as opposed to only being contacted to it) may be used.

Patterning operations may be used in selectively depositing material and/or may be used in the selective etching of material. Selectively etched regions may be selectively filled in or filled in via blanket deposition, or the like, with a different desired material. In some embodiments, the layer-by-layer build up may involve the simultaneous formation of portions of multiple layers. In some embodiments, depositions made in association with some layer levels may result in depositions to regions associated with other layer levels. Such use of selective etching and interlaced material deposited in association with multiple layers is described in U.S. patent application Ser. No. 10/434,519, by Smalley, and entitled “Methods of and Apparatus for Electrochemically Fabricating Structures Via Interlaced Layers or Via Selective Etching and Filling of Voids” which is hereby incorporated herein by reference as if set forth in full.

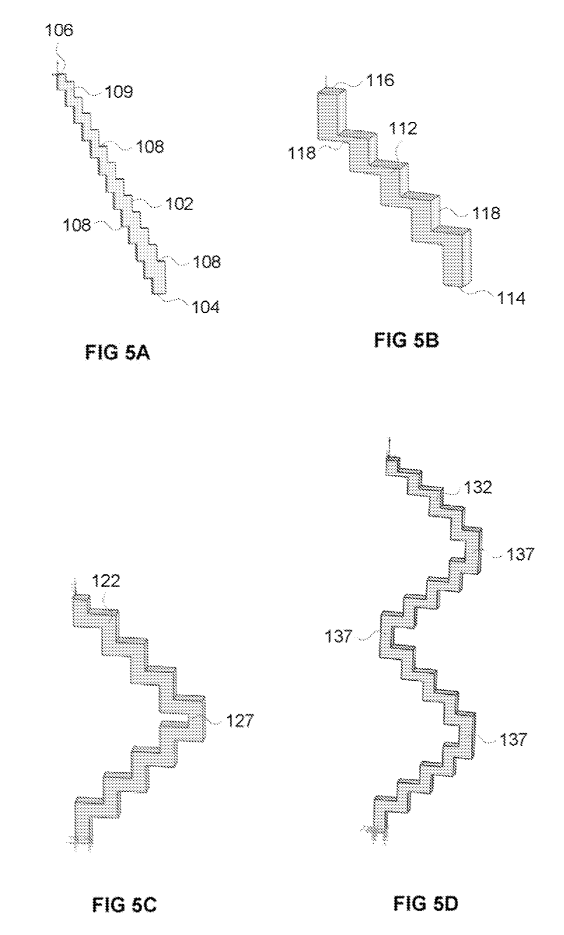

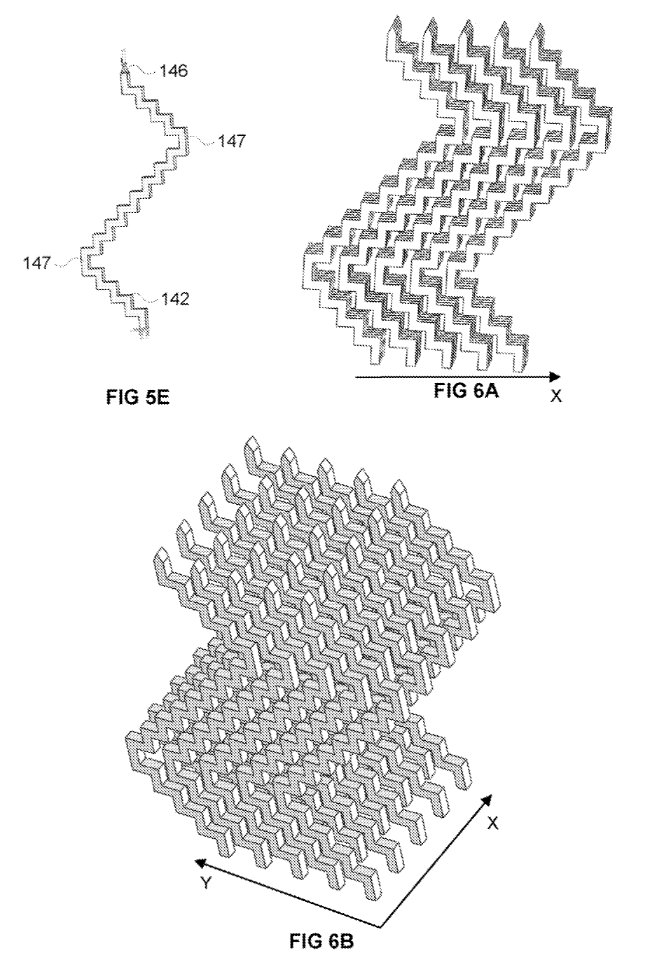

A first group of embodiments of the invention are directed to “staircase” probes, or “staircase” compliant contact elements. Two examples of simple staircase probes are shown in FIGS. 5A and 5B. These probes have a sloped elongated aspect with periodic discrete offsets. These probes 102 and 112, respectively in FIGS. 5A and 5B, have base ends 104 and 114 which may be bonded to a substrate (not shown) and contact, or tip, ends 106 and 116 which may function as contact elements or to which contact ends may be adhered (e.g. by forming on, by being formed on, or by bonding thereto). Connecting these end elements are a plurality of stepped elements 108 and 118. As may be seen from the lower steps in FIG. 5A, the steps may be defined simply by blocks that are offset (in the x-direction) from adjacent lower and adjacent higher blocks by a portion of their width. From the upper steps in FIG. 5A it may be seen that a more complex structure may also, or alternatively, exist. The upper steps indicate the horizontally offset elements are not connected directly to one another but instead are connected by a narrower vertical bridging element 109.

In some embodiments the simple stair step probes may be formed in a multi-layer electrochemical fabrication process and the steps may correspond to consecutive layer levels or to non-consecutive layer levels. In other embodiments, the probes may be formed on their sides. These probes may, for example, be formed by building up layers from the base end to the contact tip end or vice-a-versa. If the contact tip end is formed first, it may be formed on and adhered to a probe tip fabricated by a different process. Alternatively, separate probe tips may be attached to individual probes after layer formation is complete. These stair step probes may be formed using standard layer thickness processes (e.g. 2-20 micron thick layers) or using thick layer processes (e.g. 30-50 micron thick layers or more). Use of thick layer processes are preferred in some embodiments so that the probes may be made with fewer layers and to taller heights.

FIGS. 5C-5E depict somewhat more complex staircase probes. The added complexity results from the staircases folding back over themselves. The probe 122 of FIG. 5C depicts a single such fold 127, the probe 132 of FIG. 5D depicts three such folds 137, and the probe 142 of FIG. 5E depicts two such folds 147. FIG. 5E also shows that the contact tip end 146 of the probe 142 includes a pointed contact element.

FIGS. 6A and 6B depict arrays of staircase probes that are interleaved with one another so as to form arrays of tight pitch where the pitch between probes is less than the maximum horizontal extent of the probe from the base. FIG. 6A provides a perspective view of a linear array of probes having two folds while FIG. 6B provides a perspective view of a two-dimensional array of such probes. An interesting feature of these arrays involves the vertical bridging elements 109 discussed above in association with FIG. 5A. If these vertical elements exist between each horizontal offset element, arrays of identical probes that that have identical configurations may be more tightly fitted (i.e. smaller pitch between probes) than if the probes were formed by horizontal blocks sitting offset from other horizontal blocks. In fact, without the vertical bridging elements, the minimum separation between adjacent probes would need to be something greater than the maximum amount shifted between any consecutive blocks on a single probe whereas with the vertical bridging elements in place the minimum separation is something greater than zero. In other words, the minimum pitch without vertical bridges is greater than that when vertical bridges are used by the maximum of offset between any two blocks on a probe.

In alternative embodiments, the number of stair steps on each probe may be varied, the number of folds may be varied, the heights of the stair steps and of the vertical bridge elements may be varied, the widths and thicknesses of the horizontal blocks and of the vertical bridging elements may be varied. The positions of contact tips relative to the base ends, in the x-y plane may be varied (e.g. in some embodiments the tips may substantially overlie the bases. Layer thicknesses may be made to match heights of horizontal elements and of vertical bridging elements or these features may be made integral multiples of the layer thickness. Layer thickness and/or heights of features may vary from the bottom of a probe to the top of the probe. Individual staircase runs may result in substantially linear structures or they may be designed to have non-linear configurations. In still other alternative embodiments each staircase probe may be formed from two or more similar staircase probes operating in parallel with each other (e.g. placed adjacent to or slightly spaced from one another) with structural elements connecting the individual staircases together near the base end and/or the tip end and/or at periodic locations along their lengths.

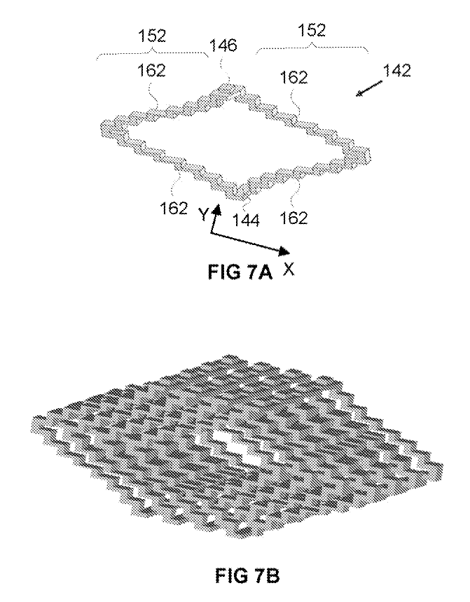

A second group of embodiments of the invention is directed to “compound staircase” probes or “jack” probes. These probes are formed from at least four linear or non-linear staircase structures 162. As can be seen in FIG. 7A, the probe 142 includes two folded staircase probes 152 joined at or near their tip and at or near their base ends. An interesting feature of some embodiments is that the joining of the two folded staircases occurs in an offset manner (e.g. offset in the y-direction). As indicated in FIG. 7A, a widened base element 144 and common tip element 146 may be formed. In some embodiments, the offsetting of the folded probe structures may occur in such a fashion that relatively short horizontal bridging elements may be used in making the join at the tip region and the join at the base region. This offsetting is performed in contrast to simply having the two folded probes abut one another in a plane that is common with the planes defined by their shapes. The offsetting of the folded staircase probes allow tighter two dimensional arrays to be formed than would otherwise be possible. Even more particularly, the small horizontal bridging elements function in a manner analogous to the vertical offset elements discussed above in association with a previous embodiment and as such allows even tighter spacing, or pitch, to be achieved. If no offset existed, tight pitch could be achieved along one axis but the pitch in the other perpendicular axis would be larger than the width of the probe as measured from fold 149 to fold 149. The use of the offset in joining the folded staircase probe elements, allows tight pitch to be achieved in both perpendicular directions (e.g. in the X and Y directions). The use of the horizontal bridging elements allows the array of probe tip elements to have a tight pitch but also to have the array of tips have the same orientation as that of the probes.

A perspective view of a two dimensional array of jack probes is shown in FIG. 7B. As noted above, the jack probe design allows interleaving of the probes to occur when used in arrays so that a very small pitch (compared to the size of the probes) is obtainable. These probes are preferably balanced so that there is no lateral motion of the probe tips as compression occurs. It is also possible for these probes to be designed to provide a twisting scrub which may help decrease contact resistance. One design element of this embodiment is that each probe is formed from two identical arms which are mirrored and offset so that they fit between neighboring probes. Each arm may take on various designs such as, for example, those discussed with regard to the staircase designs. The arms may be V shaped, W shaped, or the like. As noted above with regard to staircase probe designs, numerous alternative embodiments are possible.

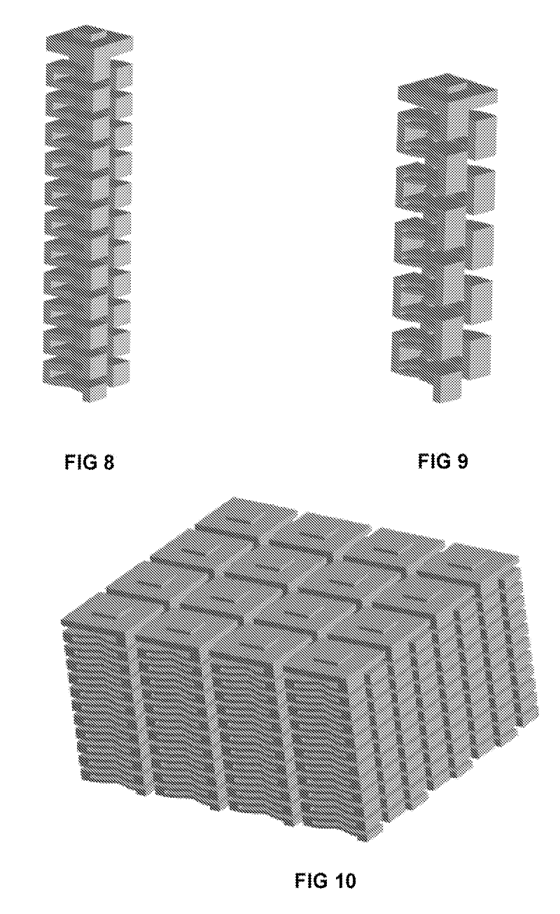

A third group of embodiments provides balanced vertical probes as illustrated in FIGS. 8-10 Vertical spring probes of this design require only three distinct masks. The design is comprised of two leaf springs that are reversed from each other so that all of the lateral forces are canceled out. FIG. 8 shows the basic design. FIG. 9 depicts a modified design where the horizontal arms of the springs are provided in pairs. FIG. 10 depicts an exemplary array of such probes.

A fourth group of embodiments provides probe structures composed of a plurality of parallel compliant elements. Stress as a function of displacement decreases as a spring segment is made softer. Making a vertical spring softer, however, reduces the total height and range usable for most designs which are formed with “series” springs (such as spirals, helices, double-helices, folded leaf springs, and the like). Series springs are characterized by a series of spring segments attached end-to-end so that they become softer as more segments are added. Making a spring segment softer, to reduce stress, requires that fewer segments be used to reach a target deflection, often defeating the design effort to reach greater travel.

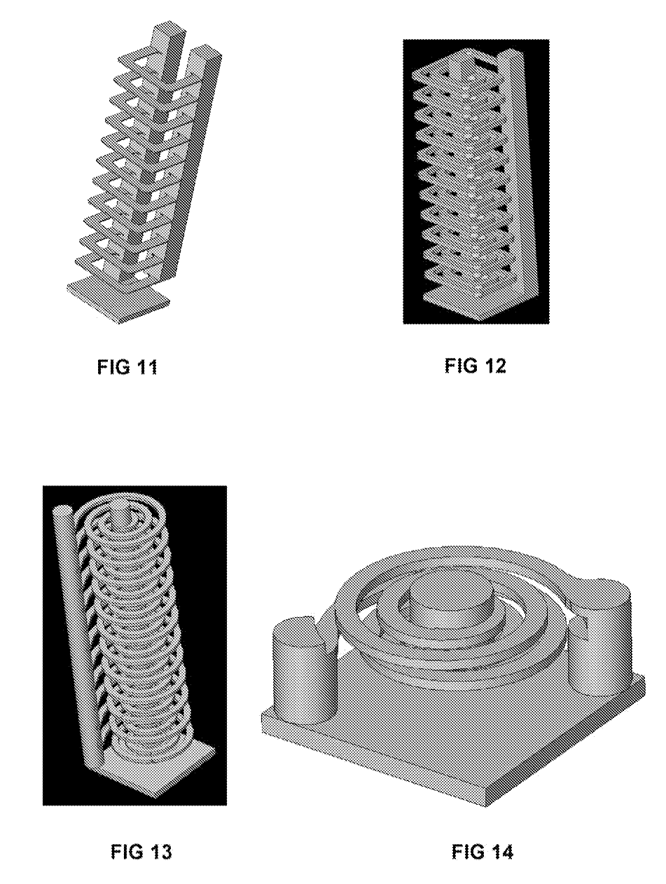

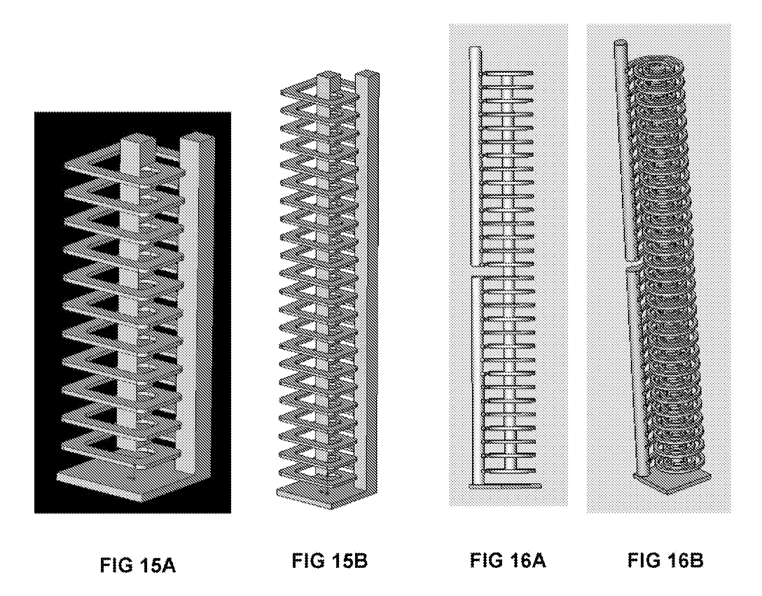

Inversely, springs can be arranged in “parallel” whereby each additional spring segment increases the stiffness. This is the type of design of this fourth group of embodiments. Examples of such probes are shown in FIGS. 11-18.

In the embodiments of this group, if only a few parallel springs (which are actually parallel in the embodiment of FIG. 11 are used the probe will be soft, whereas if many are used the probe will be stiffer. This is the opposite trend as the one encountered with compliant elements arranged in series and allows, for example, extremely soft and pliable spring segments to be grouped together to form probes of desired spring constant but greater travel range.

FIGS. 12-15B show additional examples of these springs, in each case the load is provided to the central boss and the probes can be made stiffer by simply iterating the shown structure upward.

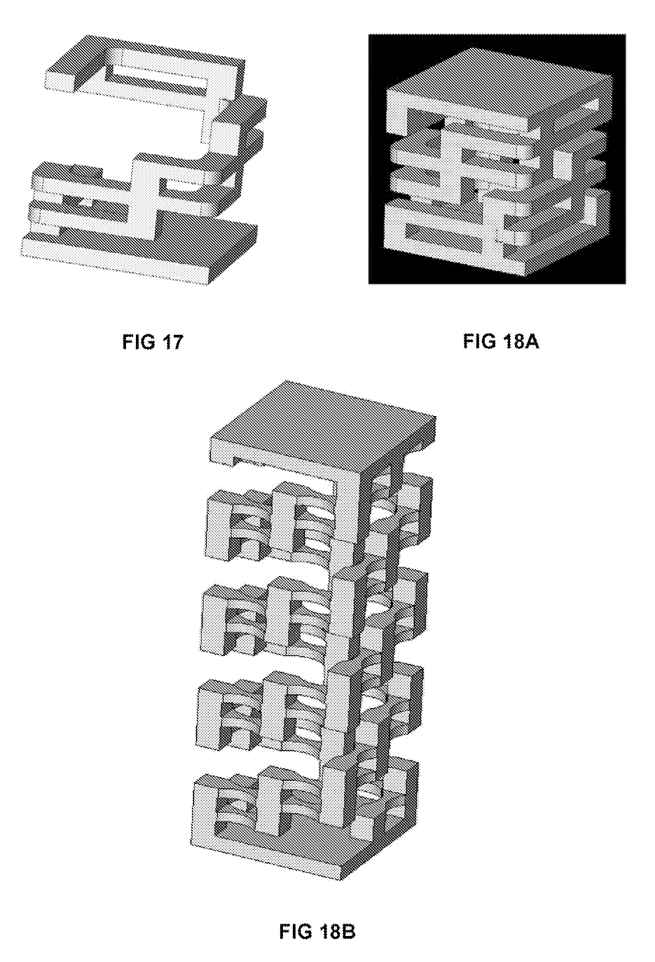

Additionally, in some embodiments, the parallel approach can be mixed with a series embodiment by hooking springs made in parallel into a series concatenation or vice versa. FIGS. 16A-16B provide an example of a parallel probe hooked in series to another parallel probe to double the available over travel. Further examples of combination springs are shown in FIGS. 17 and 18A-18B. In FIG. 17 a single spiral spring is shown where the spiral consists of a series of parallel elements. FIGS. 18A and 18B on the other hand show two double spiral spring elements with each parallel set of elements following each other in a repeating series.

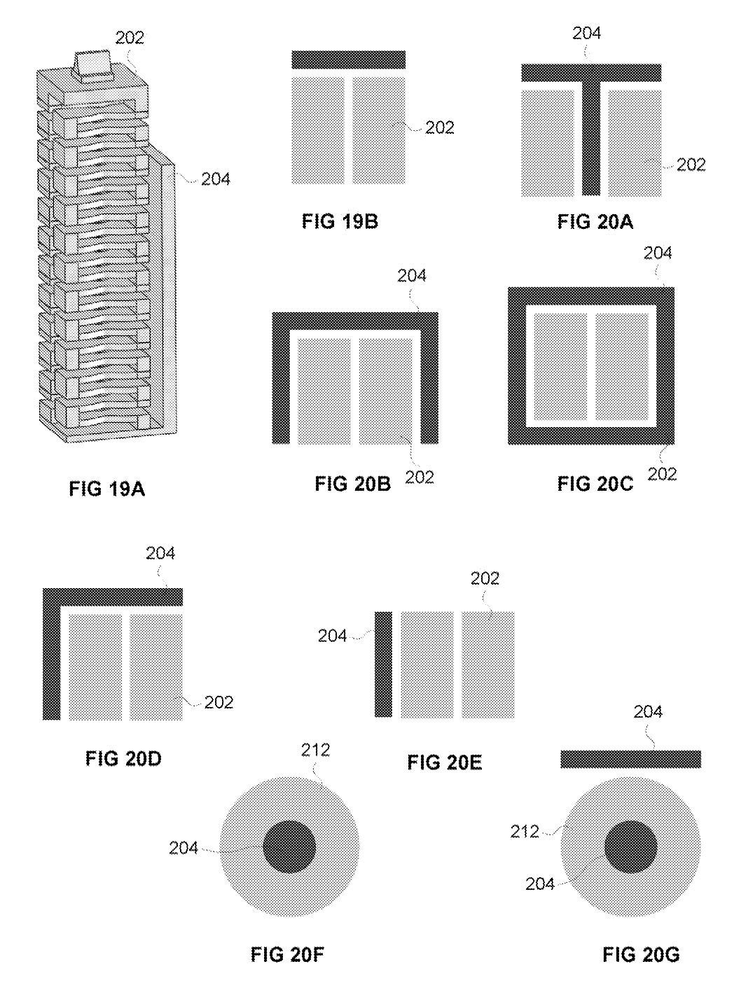

A fifth group of embodiments is illustrated in FIGS. 19A-19B and 20A-20G. In embodiments of this group lateral stiffness of vertical probes 202 and 212 is increased so that, for example, lateral movement of a wafer chuck can be used to cause relative movement between probes and target surface and thus increase the amount of scrubbing. Embodiments of this group provide a number of different ways in which a vertical probe 202 and 212 can be stiffened. For example, a probe 202 or 212 may be designed with excess lateral compliance and than a lateral stop or stops 204 of different configurations may be added to increase stiffness after a small movement bring the probe 202 or 212 and the stops 204 into contact. As illustrated in FIG. 19A, the lateral stop 204 may extend a substantial portion of the length of the probe (but not all the way). As indicated in FIGS. 19A and 19B, the support, or stop 204, can be placed on the side of the probe. As indicated in the top views of FIGS. 20A-20G other probe and support configurations can be used. The support of stop 204 may be placed inside a probe or between spaced probe elements. Another possible advantage of this design is that if adequate contact is made between the support and the probe, the electrical path of the probe may be effectively shortened, and therefore resistance, inductance, and the like reduced.

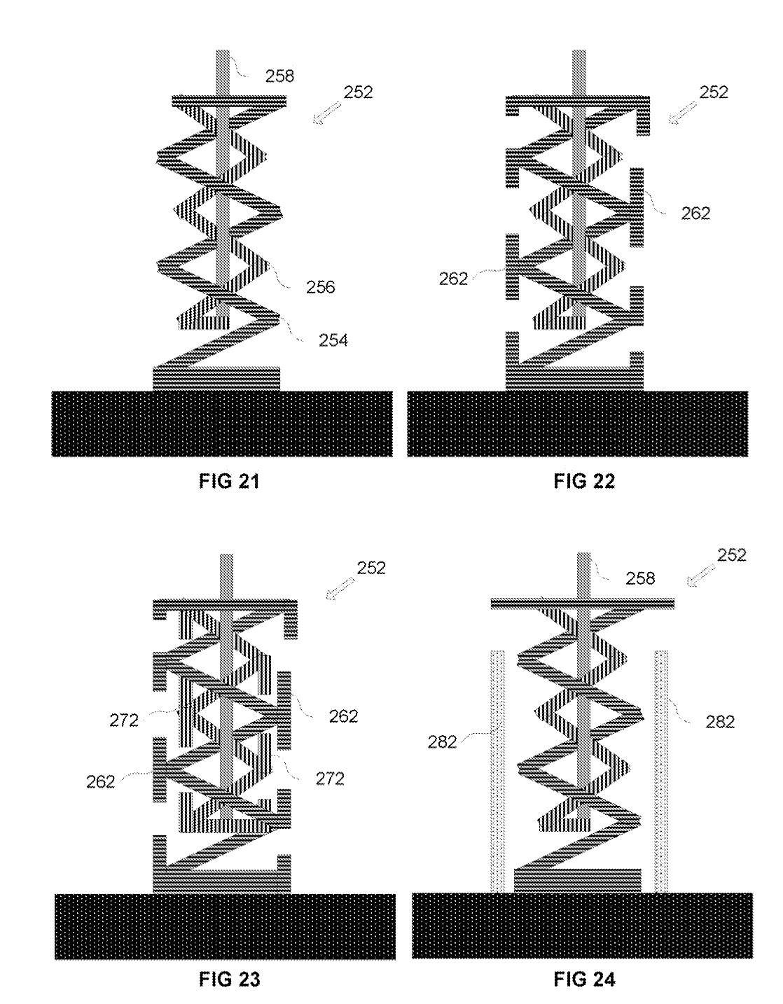

In a sixth group of embodiments (illustrated in FIGS. 21-27), a modified mechanical contact spring, or vertical electrical contact probe, design provides enhanced driving range. This concept assumes that a single spring structure cannot undergo a desired range of motion without exceeding the elastic (i.e. compliant) range of motion for the structure.

A simple version of this spring, or probe, design may be considered to include three elements: (1) an outer compliant structure, e.g. a coil, (2) an inner compliant structure, e.g. a coil, and (3) a central non-compliant structure which includes a contact structure. Each of these structural elements have two ends (a distal and a proximal end) with the following functional relationships: (1) the proximal end of the outer structure connects to a substrate (e.g. space transformer); (2) the distal end of the outer structure connects to the proximal end of the inner structure, (3) the distal end of the inner structure, connects to the proximal end of the central shaft, and (4) the distal end of the central shaft is used for making compliant mechanical or electrical contact with a desired surface (e.g. electrical contact pad). The distal and proximal ends are located upside-down relative to their immediate neighbors. In alternative embodiments, the functions of the inner and outer compliant elements may be reversed. In still other embodiments, the structures need not be provide substantially symmetrical configurations.

FIG. 21 provides a side view of a simplified example of a spring or probe structure 252 according to one example of the sixth group of embodiments. The probe 252 includes outer compliant structure 254 (e.g. an upward spiraling coil), inner compliant structure 256 (e.g. a downward spiraling coil), and central shaft 258 that extends upward through the central portions of compliant structures 254 and 256.

The drivable range of the distal end of the probe is derived from the sum of the range of compliant compressibility of the outer structure plus the range of compliant extendibility of the inner coil. In some embodiments, the inner and outer coils may have similar levels of compliance (i.e. spring constant) such that both structural elements under go compression and extension simultaneously. In other embodiments, the compliance of the structures may be significantly different such that one doesn't begin its compression or extension until the other has reached some desired displacement. In such embodiments it may be desirable to have hard stops built into the more compliant structure so that it does become over extended. In still other embodiments hard stops may be provided on both structures. In some embodiments, stops may be provided as part of the structural elements themselves or they may be provided as separate components which interact with structural elements when a certain amount of displacement has occurred. Examples of such hard stops 262 (located on the outer structural element—assumed to be the most compliant), 272 (located on both inner and outer structures), and 282 (located independently of the structural elements but with the structural elements having been modified to interact with the hard stops) are respectively shown in FIG. 22-24.

In other embodiments, the stops need not be hard stops but instead can be soft stops which simply decrease the compliance of the structural element (e.g. the stops may have some compliance associated with them).

Various other alternatives to the presented examples of the sixth group of embodiments are possible. Compliant structures, may for example, take a variety of forms: (1) circular spirals, (2) square or rectangular spirals, (3) circular structures with periodic steps, or (4) conical spirals, (5) multiple element spirals (e.g. double or triple). The inner and outer compliant structures may have similar designs (e.g. both circular spirals) or they may take on different configurations. The configurations of compliant elements may take different forms along their lengths.

If the compliant structures are in spiral configurations, the orientation of the inner spiral may be the same as the outer spiral or it may be reversed. Appropriate selection of spiral orientation, in combination with current flow considerations may be useful in reducing or tailoring the self inductance of the probe (e.g. the magnetic flux may be made to point in opposite directions in each coil). In some embodiments, the number of coils for the inner compliant structure may be equal to, less than, or greater than the number of coils in the outer compliant structure.

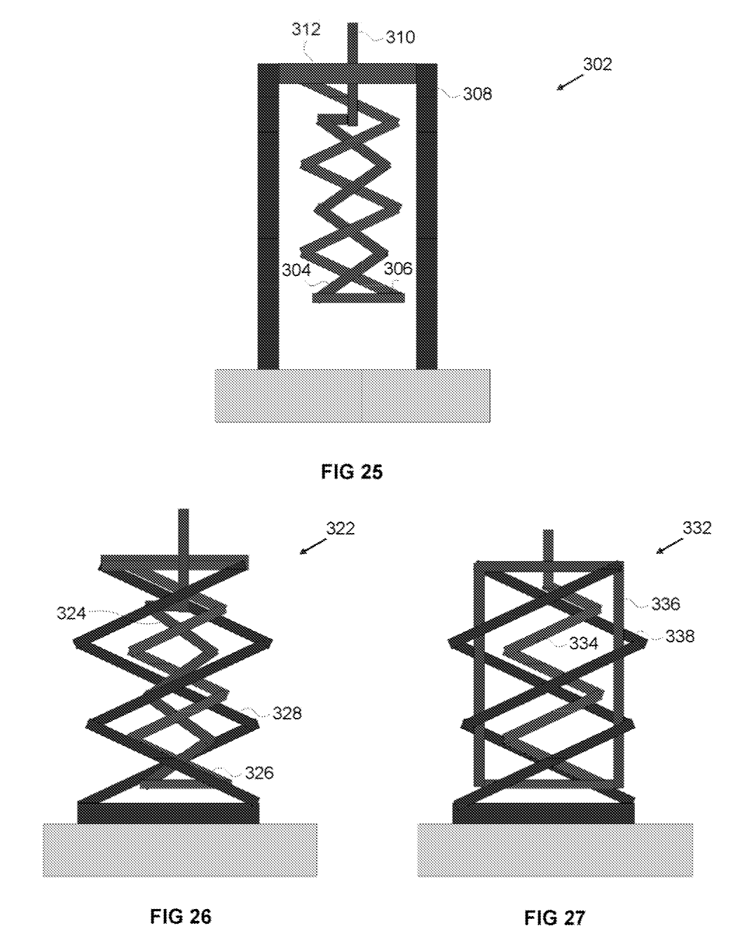

In other embodiments, third, fourth, or higher numbers of, compliant structures may be added to increase the useful deflection range of the spring structure. In some such embodiments, for example, it may be possible to replace the central shaft with another compliant element. In still other alternative embodiments, the central shaft may be replaced in favor of one or more non-compliant elements that would be located outside the outer most compliant structure or located between the compliant structures. Some such embodiments are shown in FIGS. 25-27. FIG. 25 depicts a spring structure 302 where the non-compliant elements do not form a central shaft but instead provide and outer frame 308 on which the outer compliant structure 306 may attach (it is supported from the top instead of the bottom as in FIG. 21). In FIG. 25 the inner compliant structure connects to the outer compliant structure at its bottom end while its top end forms the contact element 310 which protrudes through an opening in the top 312 of the frame 308. FIG. 26 provides a spring structure 322 with three compliant structural elements: outer 328, middle 326, and inner 324 (without any non-compliant element—other than the contact portion of the inner most compliant element). FIG. 27 provides another alternative embodiment of a spring structure 332 where the outer compliant structure 338 and the inner compliant structure 334 are connected via non-compliant structural elements 336.

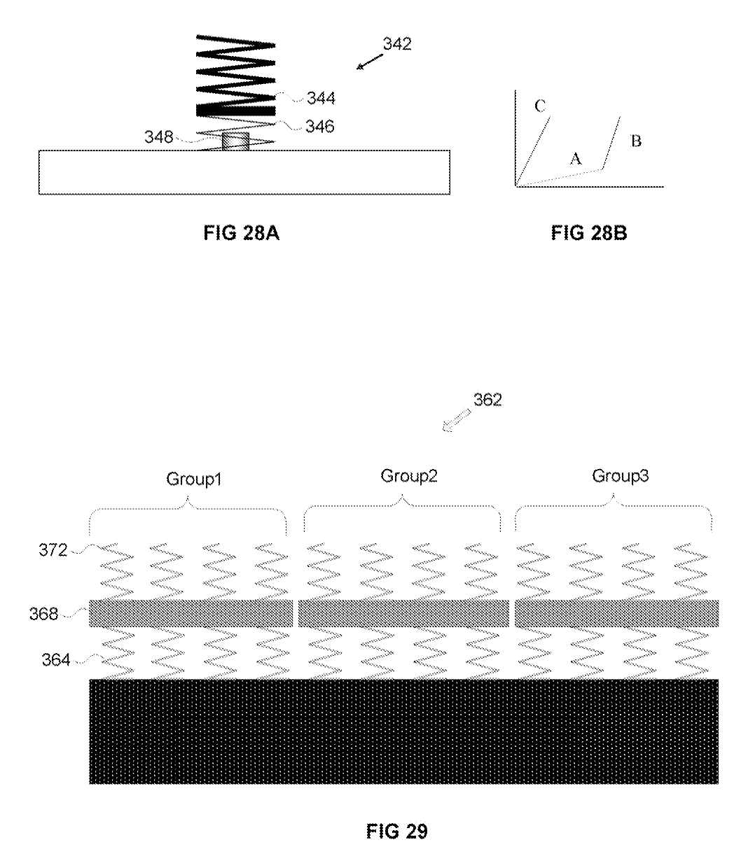

A seventh group of probe embodiments with enhanced over travel capability is illustrated in FIGS. 28A-28B. In this group of embodiments a probe element 342 is provided with a stiff spring element 344 which is attached to the end (i.e. in series) of a softer spring element 346. The softer spring element or elements 346 yield large deflection levels. But by combining a very soft spring 346, which can easily travel a large distance relative to its height, with a stiffer spring or springs 344, it is possible to greatly increase the spring travel while maintaining a desired contact force. In a further enhancement of the basis concept, a stop structure 348 may be incorporated to limit further motion of the soft spring, and to avoid excessively stressing the soft spring, once a desired level of compression has been achieved, a hard stop or at least a stop which is stiffer than the other portion of the spring may be encountered which shifts further the compressive load from the soft spring to the stiffer spring. In particular embodiments from this group it is possible to achieve a similar high load characteristic at an increased over travel without excessively stressing the soft spring or without excessively lengthening the probe. In the probe 342 (i.e. compliant spring) of FIG. 28A the bottom portion of the spring is more compliant than the top portion and upon compressive load the bottom portion of the spring bears most of the travel load initially and then after the stop is encountered, the travel load shifts to the stiffer spring. The plot of FIG. 28B illustrates a plot of load versus deflection. Line C depicts the relationship between load and over travel for single stiffness compliant element spring while the plot of A-B depicts the relationship for a dual stiffness compliant element. The soft spring provides travel (A), then when the stop is hit, the stiff spring provides required load (B). It is difficult for single stiffness springs to provide a high load and simultaneously a large travel due to material stress limitations.

FIG. 29 illustrates an design concept an eighth group of embodiments of the present invention that provide increased over travel of spring elements. In effect, this concept provides extended length compliance without having to build single spring elements to such extended heights and without having to worry about excess unintended off axis movement.

Many users of vertical probe devices have an interest in compliant probe devices that have a certain drive or displacement capability. A typical over target or over drive capability is 80-100 microns which is readily achievable for long probes but not so for relative short probes. It is believed that the desire for such displacement capability is due, at least in part, to various sources which result in non-planarity of the probe tips relative to each other or to surface that they are intended contact. Typically the substrates (e.g. space transformers) to which compliant probes are attached do not necessarily have a tight tolerance on planarity. The probes may themselves not have uniform length. The mounting of the substrate (e.g. space transformer) in a testing apparatus may not have tight co-planarity with the wafer to be tested. One way to address a customer's requirement is to build taller probes but unfortunately this results in increase build time, decreased yield, increased expense, and possibly a need to increase pitch (i.e. separation of probes) due to increased off-probing-axis displacements (e.g. XY displacements when the Z-direction is the probing direction). Other ways to address customer requirements are those presented above in FIGS. 24-27 and 28A-28B. A third way to address the requirement is to form individual probes from a base portion and an extension portion where the base portion is formed with a desired number of layers (e.g. sufficient to supply about one-half the necessary drive capability) and the extension portion is formed with a desired number of layers (e.g. sufficient to supply about one-half the necessary drive capability), before or after release of the extension and base portions from a sacrificial material, they are transfer bonded to one another. The advantage to this approach is that build height may be decreased, but some disadvantages may remain: (1) there may be issues with probe stability during or after bonding, and/or (2) there may be a need to increase pitch (separation of probes due to potential increase in displacements perpendicular to the probing-axis.

In the present group of embodiments, it is proposed that drive capability for an array of probe structures be provided in part by compliance from individual probe elements and in part from groups of probe elements which are coupled to one another.

Some potential advantages of embodiments of this group include: (1) achievement of desired over travel (not all of it is independent and thus adjacent probes may not be able to be displaced by the full drive amount), (2) achievement of stabilized x & y positioning of individual probe elements when under intended z-direction displacement, and improved array integrity and reliability.

FIG. 29 provides a side view of an example of a probe array 362 according to this group of embodiments. The probe array includes a plurality of probes divided into a plurality of groups. In the present example there are four probes per group and three groups. In this example, a primary substrate 364 supports the proximal ends of a plurality of compliant, conductive base elements 366 which have distal regions that contact or extend partially or completely through dielectric grouping structures 368. The dielectric grouping structures 368 in turn have proximal ends of conductive probe extension elements 372 mounted thereon (or extending partially or completely there through). The distal ends of the extension elements include contact tips (if desired) which are used to make contact with a desired surface, e.g. electric contact with pads of a device to be tested (not shown). In electrical applications, the distal ends of the compliant base elements and the proximal ends of the extension elements are in functional electric contact with one another. Such contact may be provided by either the base elements or the extensions elements extending through the grouping elements or by the grouping elements 108 having conductive vias to which the extension and base elements can make contact.

Though FIG. 29 shows a side view of a probe array, it should be understood that though in some embodiments the arrays may be linear arrays, in other embodiments they will be two dimensional or even three dimensional (e.g. probe tips at different heights). In some embodiments, groups may contain fewer or more probes. In some embodiments fewer or more groups may be used. In some embodiments, not all groups need have the same configuration or numbers of elements. In some embodiments multiple group structures and base elements may be stacked to obtain taller arrays and/or arrays with more drive capability.

In some embodiments, the grouping structures may be formed along with the either the extension elements or the base elements, while in other embodiments they may be formed separate from the both the extension and base elements and transfer bonding, or some other technique, used to attach the them to one or both of the extension and base elements.

In some embodiments, the dielectric grouping elements may contain conductive traces that may be used in making contact between selected probing elements (e.g. ground or power connections).

In some embodiments, extension elements and base elements may have similar structures while in other embodiments they may be different. For example, in some embodiments, the base elements may, individually, be more compliant than the extension elements. In some embodiments the number of base elements may differ from the number of extension elements.

In some embodiments, it may not be necessary to bond the distal ends of some or all of the base elements to either vias in the grouping elements or to proximal ends of the extension elements as it may be possible to use compressive contact to ensure a functional electrical connection while other elements are used to provide a stable compressive contact.

In some alternative embodiments the probe structures described herein may instead simply be mechanical spring elements for use in mechanical applications.

Other embodiments and variations of this group of embodiments are possible. Some such alternative embodiments may be derived by combining elements from this group with elements from other embodiments set forth herein.

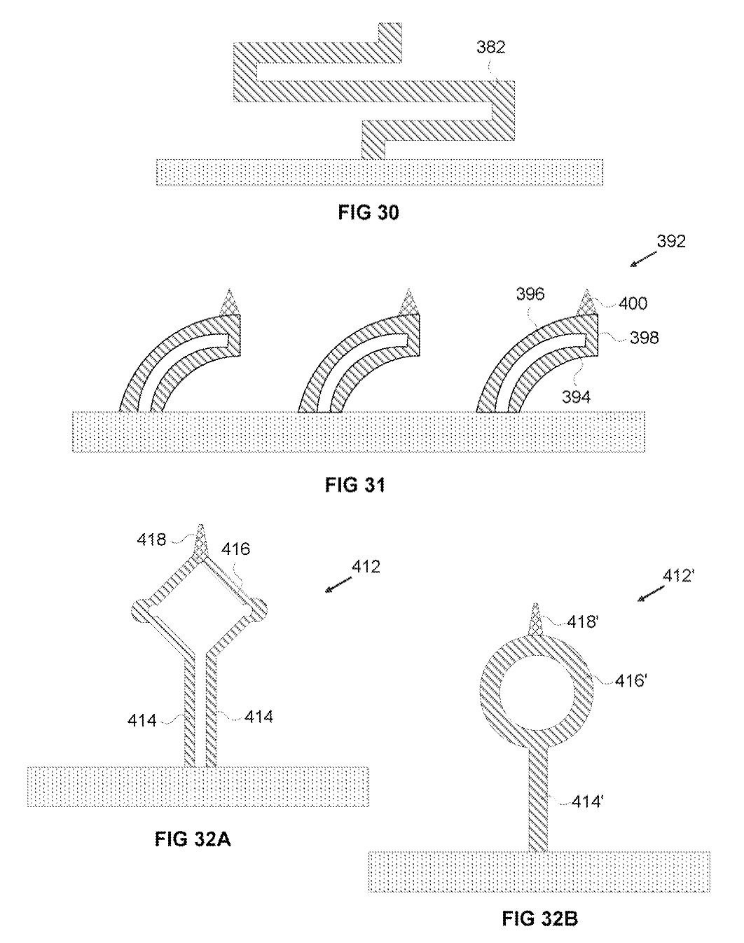

FIG. 30 provides a side view of an alternative accordion-like probe 382 that may be designed to provide a desired compliance, deflection, and the like.

FIG. 31 provides a side view of a three probe array of probe elements 392 each having unaligned mounting and contact positions (i.e. the mounting positions and the contact positions of each probe are not located along a vertical line) as well as having a longer and a shorter curved arms 394 and 396 connected to a linear bar 398 that supports a probe tip 400. When a compressive force is applied to the tip, the longer and short arms cause a different amount of horizontal displacement which cause a tilting of the probe tip 400 which in turn may cause lateral motion of the tip which may result in scrubbing of a contact pad to which the tip is contacted.

FIGS. 32A and 32B provide two examples of compliant probe structures 412 and 412′ according to an eleventh embodiment of the invention where the probe elements include at least one substantially vertical shaft 414 and 414′ upon which a symmetrical compliant element 416 and 416′ is located and in turn on which a contact tip 418 and 418′ is located.

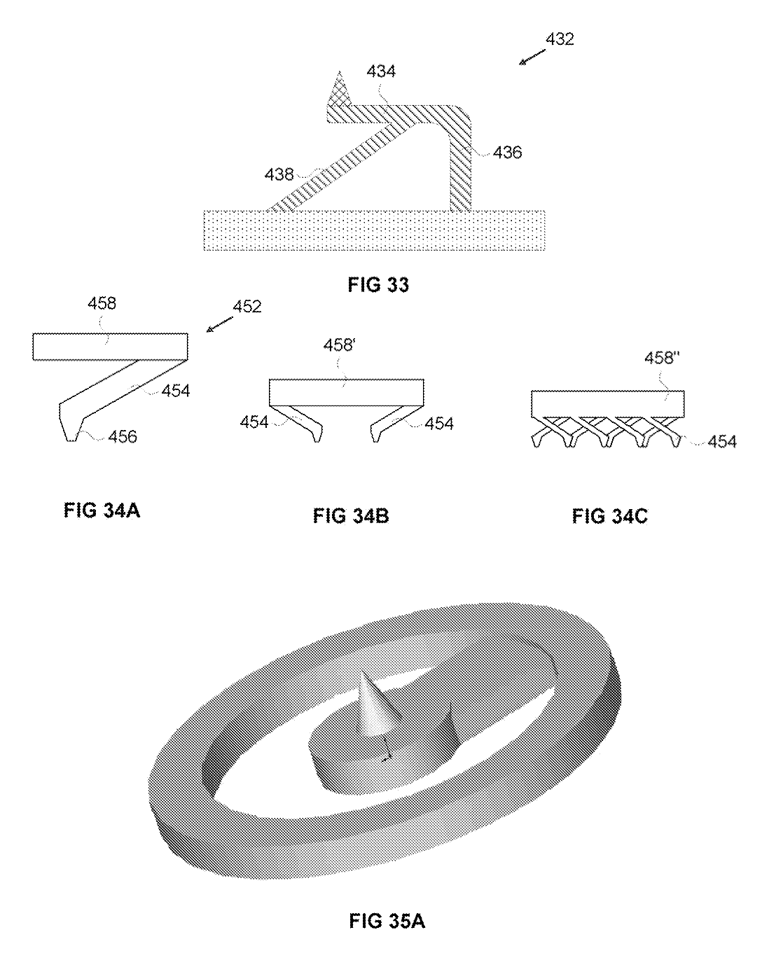

FIG. 33 provides a non-symmetric probe 432 according to a twelfth group of embodiments of the invention where a cantilever arm 434 extends from two support arms 436 and 438 one which extends back from the cantilever and the other which extends to and beyond the contact tip of the cantilever at an angle which allows buckling of the front arm to provide additional compliance when the cantilever undergoes excessive compressive force.

FIGS. 34A-34C provide schematic side views of example of diagonal extending probe tip elements 452 according to a thirteenth group of embodiments. FIG. 34A shows the bottom of a probe tip arm 454 connected to a contact tip 456 and the top of the arm 454 connected to a support ring to which the body of a probe element may attach. The probe tip provides some compliance and some scrubbing capability due to its diagonal orientation. FIG. 34B depicts two probe tips connected to a support ring 458′ while FIG. 34C depicts eight tips circling a support ring 458″.

FIGS. 35A-35B provides additional examples of self scrubbing probe tip configurations according to the thirteenth group of embodiments of the invention. In these examples tips are located at the ends of horizontal extending cantilever elements that extend toward the center of ring element to which the body of a probe element may be attached. The rings may carry one or more probe tips on cantilevered extensions as shown. When the rings undergo compression the probe tips will undergo a slight lateral displacement which may be sufficient to provide for scrubbing of a contact pad. It is possible that the lateral displacement of a single probe tip may not result in scrubbing as it may simply be taken up by lateral compliance in the probe element itself. However, when more than one probe is used to make contact the lateral displacement of more than one probe may not be countered by the lateral compliance and thus it is believed that a scrubbing motion will occur.

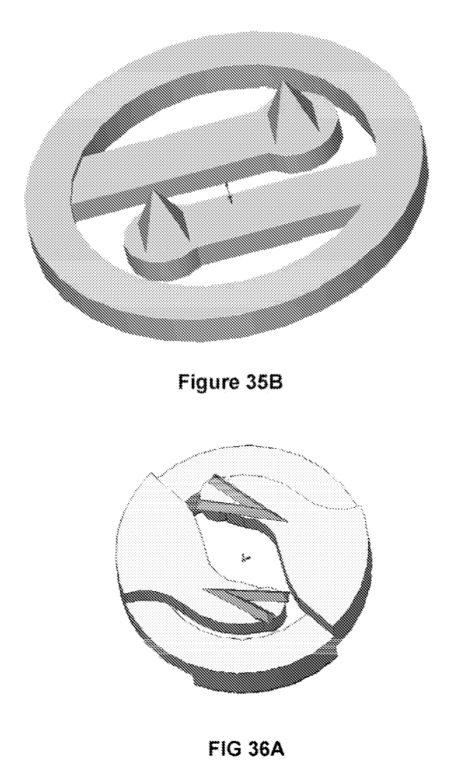

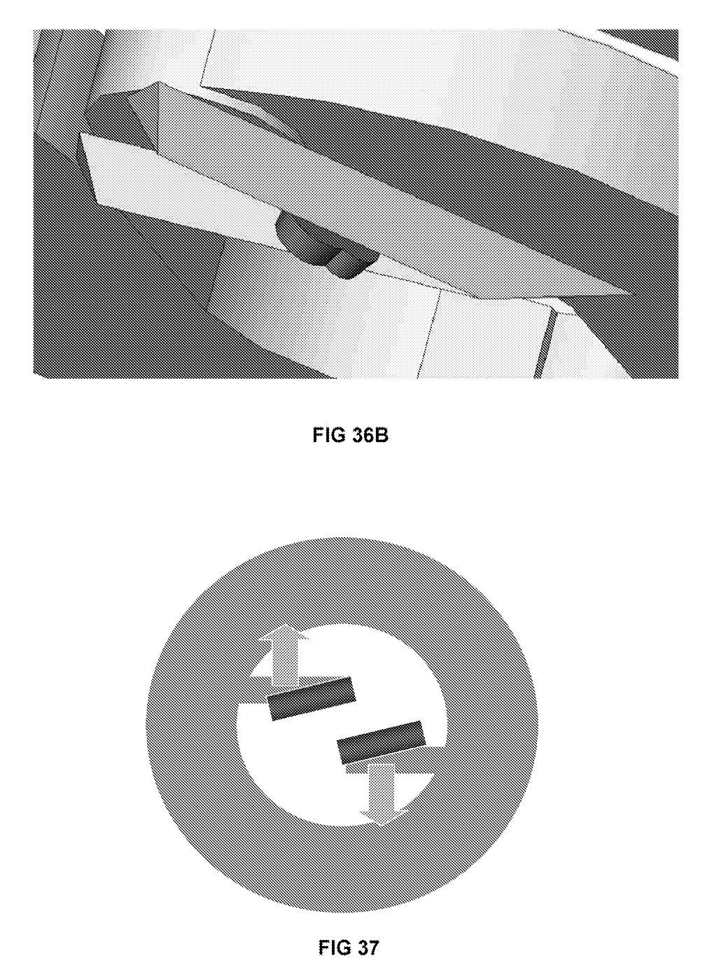

FIGS. 36A and 36B depict a probe tip design that is intended to provide self cleaning (i.e. removal of contaminates) as the probe is made to contact and scrub against a surface. The scrubbing of a probe tip is typically determined largely by the motion of the wafer versus the probe substrate. While this is acceptable, it forces a relationship between the lateral spring constant of the probe, the contact machinery, and the scrub. We can decouple these for greater flexibility by purposefully building probes with a high lateral compliance. While this would normally lead to no scrubbing due to any sideward force we can combine it with the self-scrubbing probe heads or tip configurations as previously described above to get a probe-tip system that stays where it initially contacts and scrubs only a proscribed amount. This may occur by simply maintaining a low lateral spring constant and using a self-scrubbing head.

In alternative some embodiments, it may desirable to use elongated contact tip structures and in particular structures that are not located in a direction of “cut” or scrub In these embodiments, an elongated contact structure can advantageously be situated at a designed angle in order to define a ratio of normal to tangential surface forces.

An example implementation of such an embodiment is shown in FIG. 37 as a dual-cantilever scrubbing head. In this example, the displacement of the probes carrying each head is out of the page and the sideward force generated is indicated by the arrows. The total force is therefore a torque. This results in additional “free” normal force on the contact areas that is offset by a balancing force on the opposite side. Additionally the torque can be generated in a direction counter to any spiral of the support, in which case rotational “stiffening” can result or alternatively if in a direction along the spiral rotational “softening” can result. This stiffening or softening is unique in that it scales with the force applied to the probe tips, so it can be used to make probes that have different stiffness before and after contact, this can be useful in controlling scrub land/or to help to absorb large overdrive requirements on a probe.

In other embodiments, the probe tips may take on other configurations. For example, probe tips may be hollow so that an inner ring of material may contact a pad or bump. Probe tips may have rectangular tube-like tips or circular tube-like tips. Alternatively such tips may have notches that help increase biting ability by for example decreasing contact area allowing enhanced flexibility or deformability under compression.

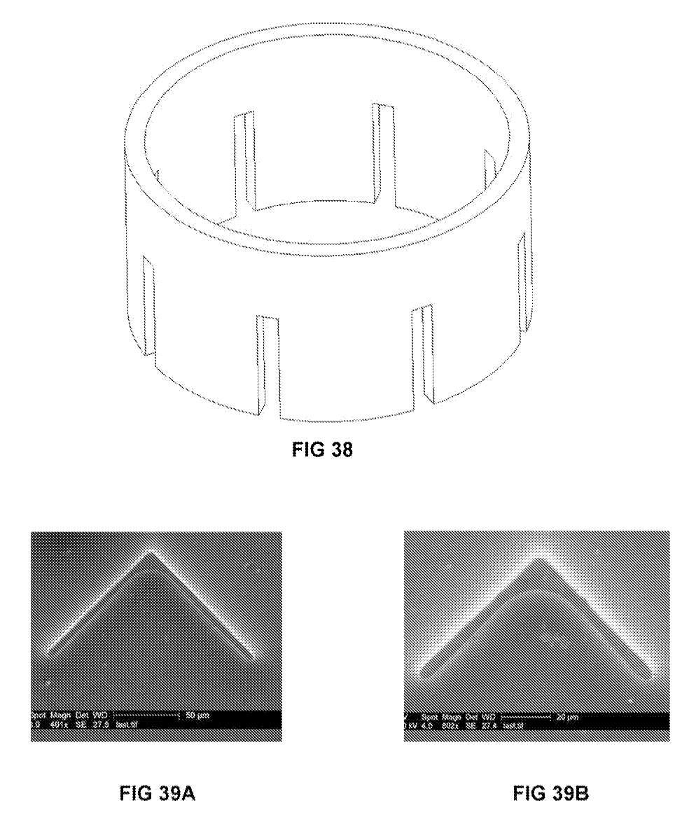

FIG. 38 provides a perspective view of a hollow cylindrical structure that may function as a probe tip in some embodiments of the invention where the contact portion of the tip comprises split segments of the cylinder that extend below its ring like base element.

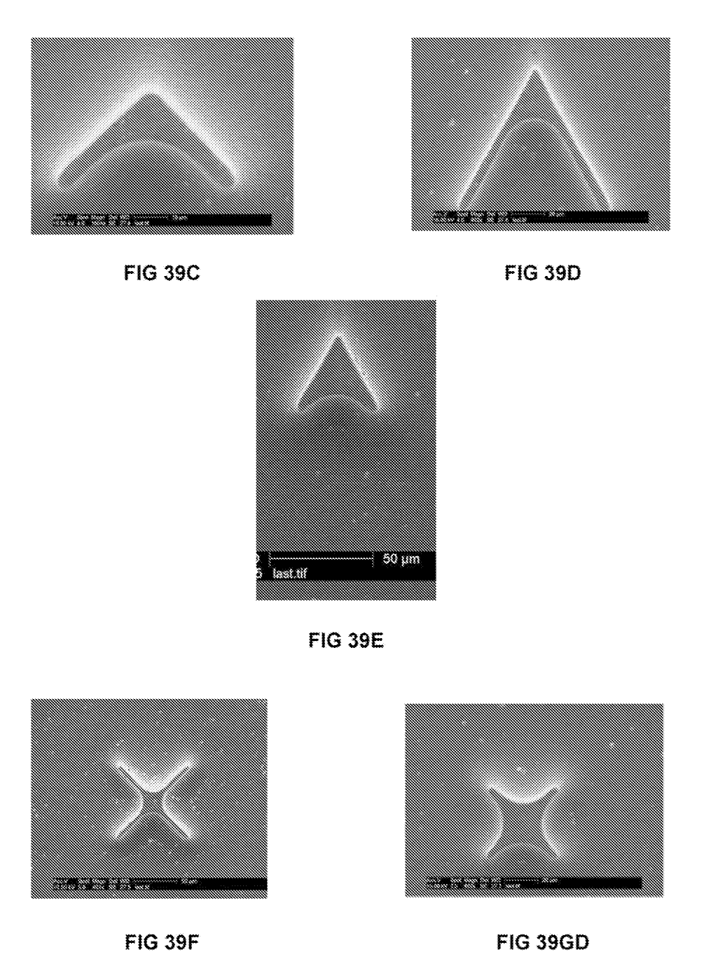

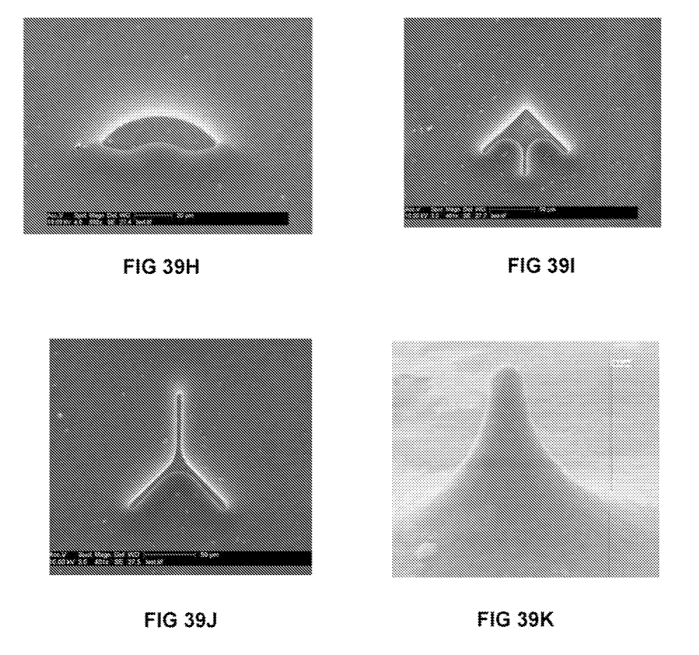

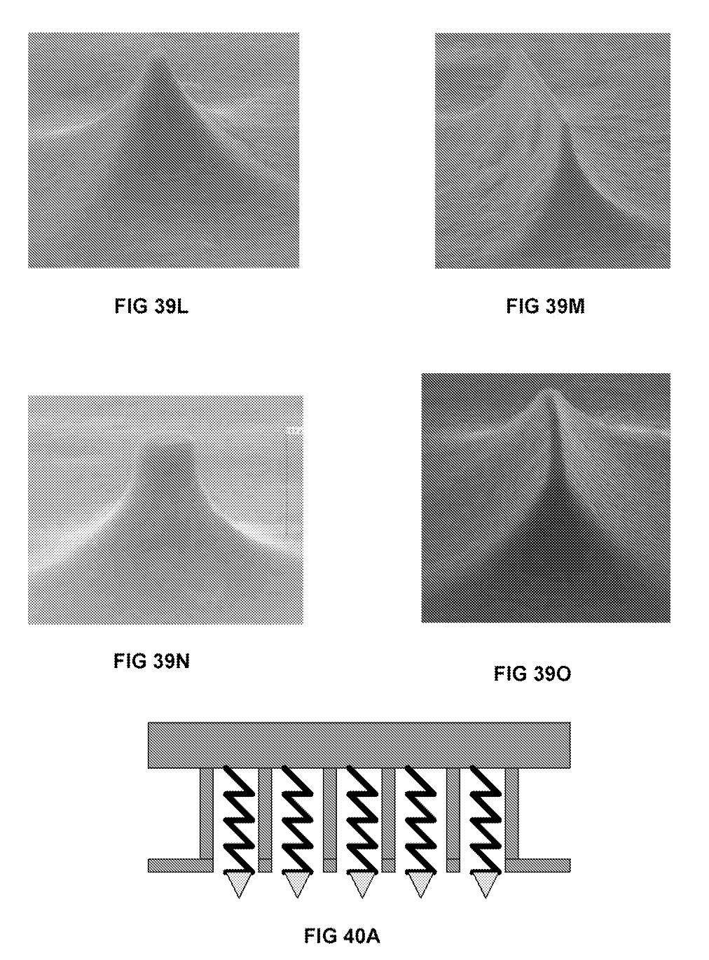

Additional example probe tip structures are shown in FIGS. 39A-39O. In particular the following configurations are shown (1) FIG. 39A: Large right angle chevron, (2) FIG. 39B: Smaller right angle chevron, (3) FIG. 39C: Even smaller right angle chevron, (4) FIG. 39D: large acute angle chevron, (5) FIG. 39E: Smaller acute angle chevron small, (6) FIG. 39F: Large cross peen for solder bumps, (7) FIG. 39G: smaller cross peen for solder bumps, (8) FIG. 39H: Crescent shape (may be used as a subcomponent to make rings or curves), (9) FIG. 39I: “Chicken foot” which is self stabilizing, (10) FIG. 39J: Triad for self stabilizing or opposed scrubbing, (10) FIGS. 39K-39O various pointed and elongated contact tip configurations. In some embodiments, probe tips may include gold, rhodium, or nickel, nickel alloys, while other materials may be used in other embodiments.

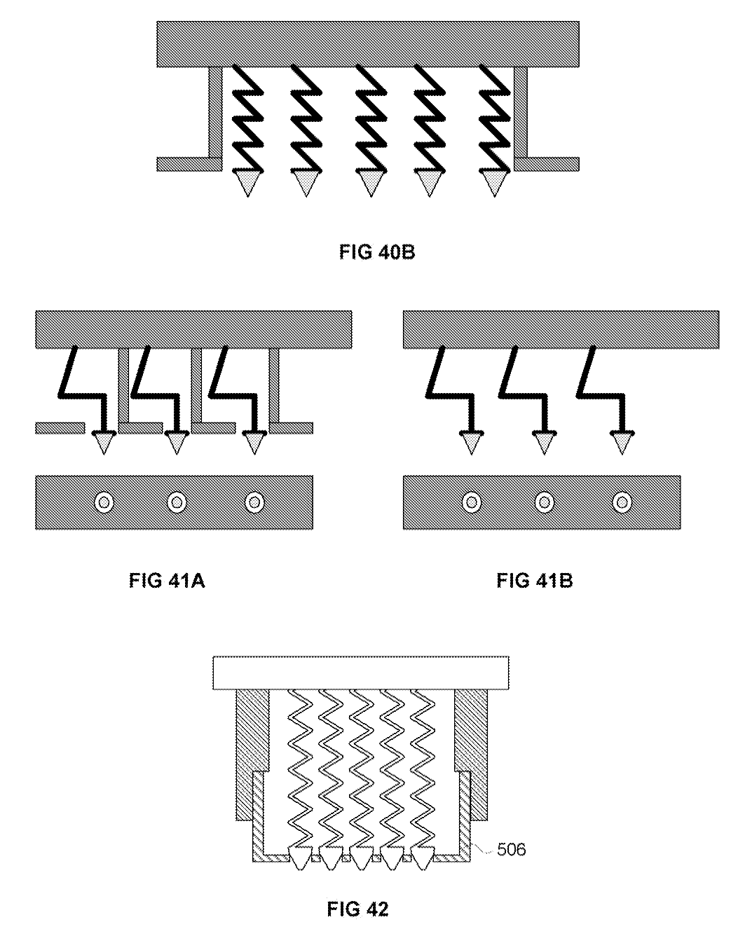

According to a fifteenth group of embodiments, shields may be provided to protect probes. Examples of such shielding is illustrated in FIGS. 40A-40B and 41A-41B. The shield also serves the purpose for preventing any lateral motion of the probes during usage. The shield may be made on one of the last layers to be fabricated. The shield may also prevent large contaminants from damaging probe springs. The anchoring of the shield to the substrate may occur between each probe or between groups of probes and any associated supports may be placed at strategic locations (e.g. in locations where probes are purposefully missing in a regular array).

FIG. 42 shows another example of a shielding structure. The shield is designed to prevent damage to vertical probes during cleaning operations (which may involve wiping motions perpendicular to the probes). The device includes a perforated plate 506 that can be lowered over the probes such that the probe tips can extend through it, but which prevents any significant lateral motion of the probes. The device may be provided with sidewalls which engage alignment features on a space transformer, or other substrate, to facilitate installation without damage to the probes. The alignment features can be co-fabricated with the probes and transferred to the space transformer along with them in good alignment. The entire device can be fabricated using electrochemical fabrication methods or via other methods.

Some embodiments may employ cathodic activation, diffusion bonding, or the like to enhance adhesion between successive layers of material. Various teachings concerning the use of diffusion bonding in electrochemical fabrication processes are set forth in U.S. patent application Ser. No. 10/841,384 which was filed May 7, 2004 by Cohen et al. which is entitled “Method of Electrochemically Fabricating Multilayer Structures Having Improved Interlayer Adhesion” and which is hereby incorporated herein by reference as if set forth in full. Various teachings concerning cathodic activation are set forth in U.S. patent application Ser. No. 10/434,289 which was filed on May 7, 2003 by Zhang, and entitled “Conformable Contact Masking Methods and Apparatus Utilizing In Situ Cathodic Activation of a Substrate”. These applications are hereby incorporated herein by reference as if set forth in full.

Further teaching about microprobes and electrochemical fabrication techniques are set forth in a number of US patent applications which were filed on Dec. 31, 2003. These Filings include: (1) U.S. Patent Application No. 60/533,933, by Arat et al. and which is entitled “Electrochemically Fabricated Microprobes”; (2) U.S. Patent Application No. 60/533,975, by Kim et al. and which is entitled “Microprobe Tips and Methods for Making”; (3) U.S. Patent Application No. 60/533,947, by Kumar et al. and which is entitled “Probe Arrays and Method for Making”; and (4) U.S. Patent Application No. 60/533,948, by Cohen et al. and which is entitled “Electrochemical Fabrication Method for Co-Fabricating Probes and Space Transformers”. Furthermore, the techniques disclosed explicitly herein may benefit by combining them with the techniques disclosed in U.S. patent application Ser. Nos. 11/177,798, filed Jul. 7, 2005; 11/173,241, filed Jun. 30, 2005; 11/029,221, filed Jan. 3, 2005; 11/029,180, filed Jan. 3, 2005; 11/028,960, filed Jan. 30, 2005; and 11/029,217, filed Jan. 3, 2005. These patent filings are each hereby incorporated herein by reference as if set forth in full herein.

Further teachings about planarizing layers and setting layers thicknesses and the like are set forth in the following US patent applications which were filed Dec. 31, 2003: (1) U.S. Patent Application No. 60/534,159 by Cohen et al. and which is entitled “Electrochemical Fabrication Methods for Producing Multilayer Structures Including the use of Diamond Machining in the Planarization of Deposits of Material” and (2) U.S. Patent Application No. 60/534,183 by Cohen et al. and which is entitled “Method and Apparatus for Maintaining Parallelism of Layers and/or Achieving Desired Thicknesses of Layers During the Electrochemical Fabrication of Structures”. Furthermore, the techniques disclosed explicitly herein may benefit by combining them with the techniques disclosed in U.S. patent application Ser. No. 11/029,220, filed Jan. 3, 2005 by Frodis et al. and entitled “Method and Apparatus for Maintaining Parallelism of Layers and/or Achieving Desired Thicknesses of Layers During the Electrochemical Fabrication of Structures”. These patent filings are each hereby incorporated herein by reference as if set forth in full herein.

Additional teachings concerning the formation of structures on dielectric substrates and/or the formation of structures that incorporate dielectric materials into the formation process and possibility into the final structures as formed are set forth in a number of patent applications: (1) U.S. Patent Application No. 60/534,184, by Cohen, which as filed on Dec. 31, 2003, and which is entitled “Electrochemical Fabrication Methods Incorporating Dielectric Materials and/or Using Dielectric Substrates”; (2) U.S. Patent Application No. 60/533,932, by Cohen, which was filed on Dec. 31, 2003, and which is entitled “Electrochemical Fabrication Methods Using Dielectric Substrates”; (3) U.S. Patent Application No. 60/534,157, by Lockard et al., which was filed on Dec. 31, 2004, and which is entitled “Electrochemical Fabrication Methods Incorporating Dielectric Materials”; (4) U.S. Patent Application No. 60/574,733, by Lockard et al., which was filed on May 26, 2004, and which is entitled “Methods for Electrochemically Fabricating Structures Using Adhered Masks, Incorporating Dielectric Sheets, and/or Seed Layers that are Partially Removed Via Planarization”; and U.S. Patent Application No. 60/533,895, by Lembrikov et al., which was filed on Dec. 31, 2003, and which is entitled “Electrochemical Fabrication Method for Producing Multi-layer Three-Dimensional Structures on a Porous Dielectric”. Furthermore, the techniques disclosed explicitly herein may benefit by combining them with the techniques disclosed in U.S. patent application Ser. No. 11/029,216 filed Jan. 3, 2005 by Cohen et al. and entitled “Electrochemical Fabrication Methods Incorporating Dielectric Materials and/or Using Dielectric Substrates” (corresponding to Microfabrica Docket No. P-US128-A-MF) and U.S. patent application Ser. No. ______ filed concurrently herewith by Dennis R. Smalley et al., and entitled “Method of Forming Electrically Isolated Structures Using Thin Dielectric Coatings” (corresponding to Microfabrica Docket No. P-US152-A-MF). These patent filings are each hereby incorporated herein by reference as if set forth in full herein.

Furthermore, U.S. application Ser. Nos. 10/677,556, filed Oct. 1, 2003; 60/415,374, filed Oct. 1, 2002; 11/028,958, filed Jan. 3, 2005; 10/028,945, filed Jan. 3, 2005; 11/028,960, filed Jan. 3, 2005; 10/434,493, filed May 7, 2003; 60/379,177, filed May 7, 2002; 60/442,656, filed Jan. 23, 2003; 60/574,737, filed May 26, 2003; 60/582,689, filed Jun. 23, 2004; 60/582,690, filed Jun. 23, 2004; 60/609,719, filed Sep. 13, 2004; and 60/611,789, filed Sep. 20, 2004 are incorporated herein by reference. Many other alternative embodiments will be apparent to those of skill in the art upon reviewing the teachings herein.

Further embodiments may be formed from a combination of the various teachings explicitly set forth in the body of this application. Even further embodiments may be formed by combining the teachings set forth explicitly herein with teachings set forth in the various applications and patents referenced herein, each of which is incorporated herein by reference. In view of the teachings herein, many further embodiments, alternatives in design and uses of the instant invention will be apparent to those of skill in the art. As such, it is not intended that the invention be limited to the particular illustrative embodiments, alternatives, and uses described above but instead that it be solely limited by the claims presented hereafter.

We claim:

1. A compliant probe device for making electric contact with an electronic component, comprising:
(A) a tip element;
(B) an elongated compliant element formed from a plurality of adhered layers of a deposited material adhered to the tip element,
wherein at least one of the following criteria is met:
(1) the elongate compliant element comprises a plurality of steps with a number of the steps separated from adjacent steps by a bridge of material that is common to a lower adjacent step and a higher adjacent step;
(2) the elongate compliant element comprises at least two compliant springs that are oriented so as to provide balanced compliance under compressive force;
(3) the compliant element comprises a plurality of compliant spring elements located in parallel;
(4) the compliant element comprises a plurality of compliant elements a portion of which are in parallel to each other and a portion which are in series with each other;
(5) the compliant element is located in proximity to a stiffening element such that lateral displacement of the compliant element is hindered upon contact with the stiffening element;
(6) the compliant element comprises a first spring element in series with a second spring element wherein during compression the first spring element is placed in a net compressive state while the second spring element is placed in a net tensional state; or
(7) the compliant element comprises a first spring element in series with a second spring element, where the first spring element has a first compliance and the second spring element has a second compliance and where the first and second compliance are different.

2. A compliant probe array for making electric contact with an electronic component, comprising:
(A) a plurality of tip elements;
(B) a plurality of elongated compliant elements formed from a plurality of adhered layers of a deposited material with each elongate compliant element adhered to a respect tip element,
wherein at least one of the following criteria is met:
(1) the array is formed of elongate compliant elements with each comprising a plurality of steps with a number of the steps separated from adjacent steps by a bridge of material that is common to a lower adjacent step and a higher adjacent step wherein the bridging elements provide a spacing necessary to position adjacent probe elements apart from one another by a distance which is less than a cross-sectional width of the elongate elements; or
(2) the array is formed of elongate compliant extension elements that may move independently of other elongate compliant extension elements which are position is series with a plurality of elongate compliant base elements whose movement is coupled to other compliant base elements but a bridging element that is located between the elongate compliant extension elements and the elongate compliant base elements.
